(19) United States
(12) Patent Application Publication
(10) Pub. No.: US 2025/0380457 A1
(43) Pub. Date: Dec. 11, 2025

(54) METHOD FOR FORMING A SEMICONDUCTOR STRUCTURE

(71) Applicant: Taiwan Semiconductor Manufacturing Co., Ltd., Hsinchu (TW)

(72) Inventors: Chih-Ching WANG, Hsinchu (TW); Zhiqiang WU, Hsinchu (TW); Sean MA, Hsinchu (TW); Kuo-Cheng CHIANG, Hsinchu (TW)

(21) Appl. No.: 18/919,138

(22) Filed: Oct. 17, 2024

Related U.S. Application Data
(60) Provisional application No. 63/656,990, filed on Jun. 6, 2024.

(51) Int. Cl. H01L 29/423; H01L 21/8234; H01L 27/088; H01L 29/06; H01L 29/66; H01L 29/775; H01L 29/786

(52) U.S. Cl. CPC H10D 30/6735; H10D 30/014; H10D 30/43; H10D 30/6757; H10D 62/115; H10D 62/121; H10D 64/018; H10D 84/0128; H10D 84/013; H10D 84/038; H10D 84/83

(57) ABSTRACT

A method of forming an integrated circuit includes forming a sacrificial semiconductor nanostructure and a dielectric interposer adjacent to each other between two stacked channels of a gate all around transistor. The method includes forming an inner spacer in contact with the dielectric interposer. The channels are released by removing the sacrificial semiconductor nanostructure and the dielectric interposer.

### BACKGROUND

The semiconductor integrated circuit industry has experienced exponential growth. Technological advances in integrated circuit materials and design have produced generations of integrated circuits where each generation has smaller and more complex circuits than the previous generation. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1-15 are cross-sectional views of an integrated circuit at various stages of processing, in accordance with some embodiments.

FIG. 16A-27 are cross-sectional views of an integrated circuit at various stages of processing, in accordance with some embodiments.

FIG. 28 is a flow diagram of a method of manufacturing an integrated circuit, in accordance with some embodiments.

FIG. 29 is a flow diagram of a method of manufacturing an integrated circuit, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The present disclosure is generally related to semiconductor devices, and more particularly to field-effect transistors (FETs), such as planar FETs, three-dimensional fin FETs (FinFETs), or nanostructure devices. Examples of nanostructure devices include gate-all-around (GAA) devices, nanosheet FETs (NSFETs), nanowire FETs (NWFETs), and the like. In advanced technology nodes, active area spacing between nanostructure devices is generally uniform, source/drain epitaxy structures are symmetrical, and a metal gate surrounds four sides of the nanostructures (e.g., nanosheets).

Embodiments of the disclosure provide an integrated circuit having gate all around transistors that receive the benefits of utilization of both sacrificial semiconductor nanostructures and dielectric interposers. At N-type transistors, sacrificial semiconductor nanostructure interposers are recessed, and dielectric interposers are formed in the recesses. The dielectric interposers are then likewise recessed and inner spacers are then formed in the remaining recesses adjacent to the recessed dielectric interposers. The result is that N-type transistors do not suffer the drawbacks of full utilization of dielectric interposers and retain the beneficial strain from utilization of sacrificial semiconductor nanostructures as interposers. The P-type transistors either utilize the same recessed dielectric interposers or may utilize full dielectric interposers, thereby providing the P-type transistors with the beneficial strain of utilization of dielectric interposers. Furthermore, damage to interlevel dielectric layers and trench isolation regions by removal of full dielectric interposers is reduced. The result is transistors with higher performance and integrated circuits with less damage. Accordingly, wafer yields increase in addition to device performance.

While the figures and description focus primarily on examples in which the transistors are nanostructure transistors including stacks of channels, principles of the present disclosure extend to other types of transistors. Principles of the present disclosure extend to MOS transistors, FinFET transistors and other types of transistors.

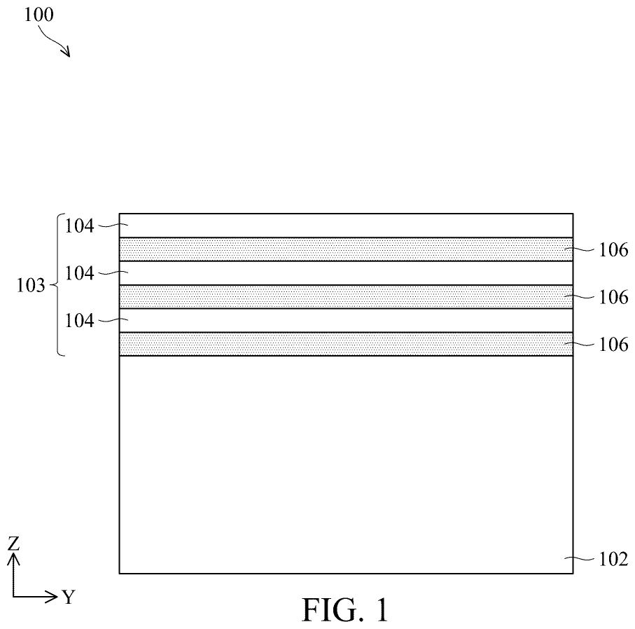

FIGS. 1-15 are cross-sectional views of an integrated circuit 100 fabricated in accordance with some embodiments of the present disclosure. The fabrication process results in a plurality of transistors 101, as will be described in further detail below.

FIG. 1 is a cross-sectional view of the integrated circuit 100 at an intermediate stage of processing. The integrated circuit 100 includes a substrate 102. The substrate 102 may be a semiconductor substrate, such as a bulk semiconductor, or the like, which may be doped (e.g., with a P-type or an N-type dopant) or undoped. The semiconductor material of the substrate 102 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

The integrated circuit 100 includes a semiconductor stack 103 including a plurality of semiconductor layers 104 and sacrificial semiconductor layers 106 alternating with each other. As will be set forth in further detail below, the semiconductor layers 104 will be patterned to form stacked channels of a plurality of transistors. As set forth in more detail below, the sacrificial semiconductor layers 106 will eventually be entirely removed and are utilized to enable forming gate metals and other structures around the semiconductor nanostructures. In FIG. 1, three semiconductor layers 104 and three sacrificial semiconductor layers 106 are illustrated. In some embodiments, the multi-layer stack 103 may include fewer or more layers than are shown in FIG. 1.

In some embodiments, the semiconductor layers 104 may be formed of a first semiconductor material suitable, such as silicon, silicon carbide, or the like, and the sacrificial semiconductor layers 106 may be formed of a second semiconductor material, such as silicon germanium or the like. Each of the layers of the multi-layer stack 103 may be epitaxially grown using a process such as chemical vapor deposition (CVD), atomic layer deposition (ALD), vapor phase epitaxy (VPE), molecular beam epitaxy (MBE), or the like.

Due to high etch selectivity between the materials of the semiconductor layers 104 and the sacrificial semiconductor layers 106, the sacrificial semiconductor layers 106 of the second semiconductor material may be removed without significantly etching the semiconductor layers 104 of the first semiconductor material, thereby allowing the semiconductor layers 104 to be released to form stacked channel regions of transistors, as will be set forth in more detail below.

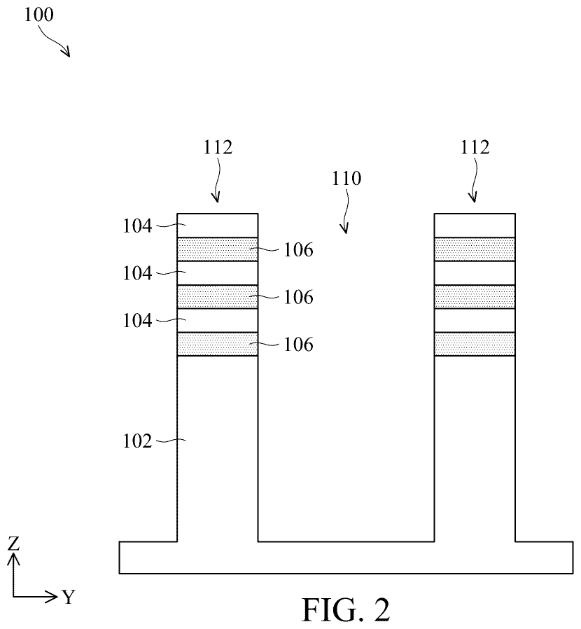

In FIG. 2, trenches 110 have been formed in the stack 103 and in the substrate 102. Though not shown in FIG. 1, a hard mask layer is first formed and patterned on the stack 103. The trenches 110 can be formed with an anisotropic etching process that etches in the downward direction in the presence of the patterned hard mask. The etching process defines semiconductor fins 112 by forming trenches 110 through the sacrificial semiconductor layers 106, the semiconductor layers 104, and the substrate 102.

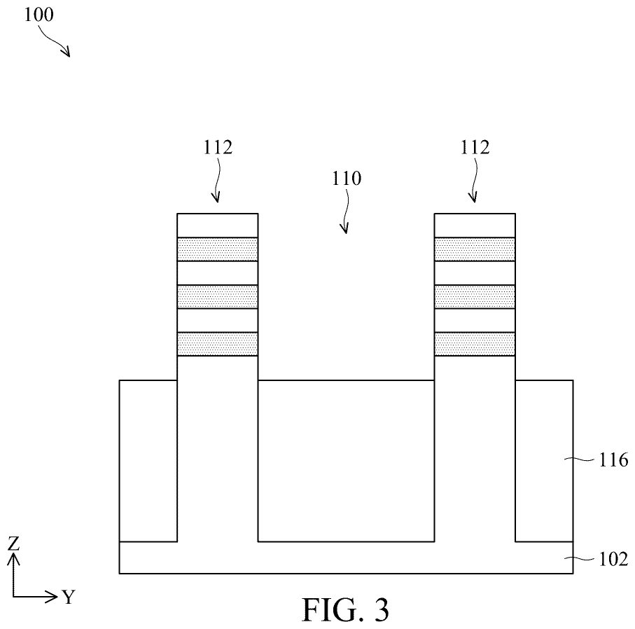

FIG. 3 is a cross-sectional Y-view, in accordance with some embodiments. In FIG. 3, shallow trench isolation regions 116 have been formed by depositing a dielectric material in the trenches 110 between fins 112. The shell dielectric layer may be deposited by chemical vapor deposition (CVD), atomic layer deposition (ALD), physical vapor deposition (PVD), or other suitable deposition processes. In an exemplary embodiment, the dielectric material includes silicon oxide. However, the dielectric material can include SIN, SiCN, SiOC, SiOCN, or other dielectric materials without departing from the scope of the present disclosure. After deposition of the dielectric material, an etch-back process has been performed to recess the top of the shallow trench isolation regions 116 below the lowest sacrificial semiconductor layers 106.

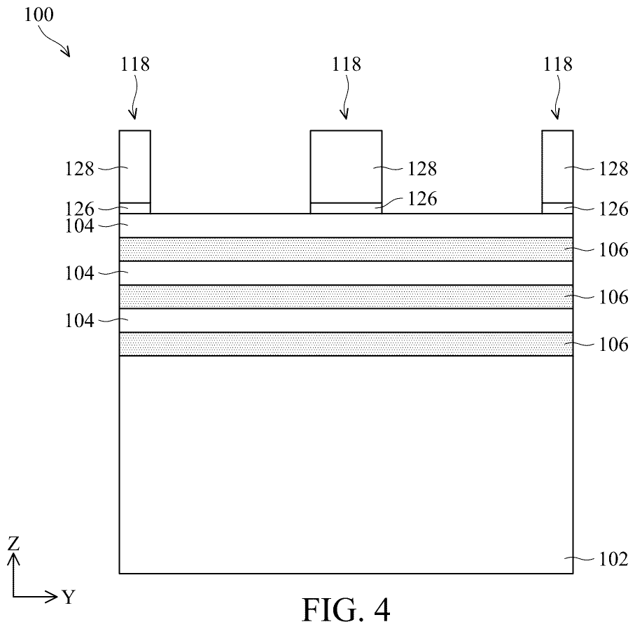

FIG. 4 is an X-view of the integrated circuit 100, in accordance with some embodiments. In FIG. 4, sacrificial gate structures 118 have been formed over the fins 112.

The sacrificial gate structures 118 extend in the Y direction, perpendicular to the fins 112. In practice, each sacrificial gate structure 118 crosses multiple fins 112. The sacrificial gate structures 118 are also formed in the trenches 110.

The sacrificial gate structures 118 include a dielectric layer 126. In an exemplary embodiment, the dielectric layer 126 includes silicon oxide. However, alternatively, the dielectric layer 126 can include SIN, SiCN, SiOC, SiOCN, or other dielectric materials without departing from the scope of the present disclosure. In some embodiments, the dielectric layer 126 has a low K dielectric material. The dielectric layer 126 can be deposited by CVD, ALD, or PVD.

The sacrificial gate structures include a sacrificial gate layer 128 on the dielectric layer 126. The sacrificial gate layer 128 can include materials that have a high etch selectivity with respect to the trench isolation regions 116. In an exemplary embodiment, sacrificial gate layer 128 includes polysilicon. However, the sacrificial gate layer 128 may be a conductive, semiconductive, or non-conductive material and may be or include amorphous silicon, poly-crystalline silicon-germanium (poly-SiGe), metallic nitrides, metallic silicides, metallic oxides, and metals. The sacrificial gate layer 128 may be deposited by physical vapor deposition (PVD), CVD, sputter deposition, or other techniques for depositing the selected material. Though not shown in FIG. 4, in some embodiments, the sacrificial gate structures 118 may include additional dielectric layers above the sacrificial gate layer 128.

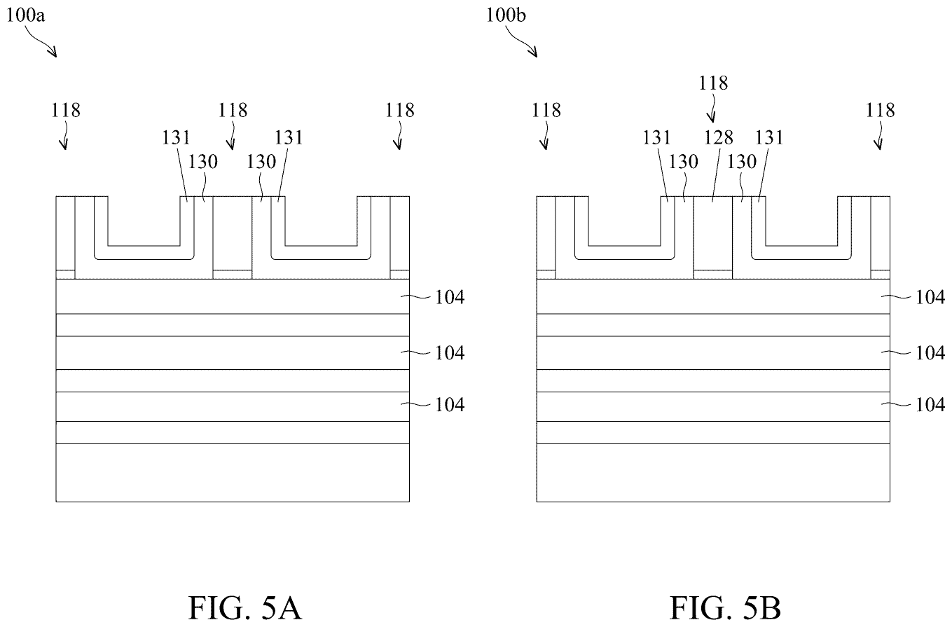

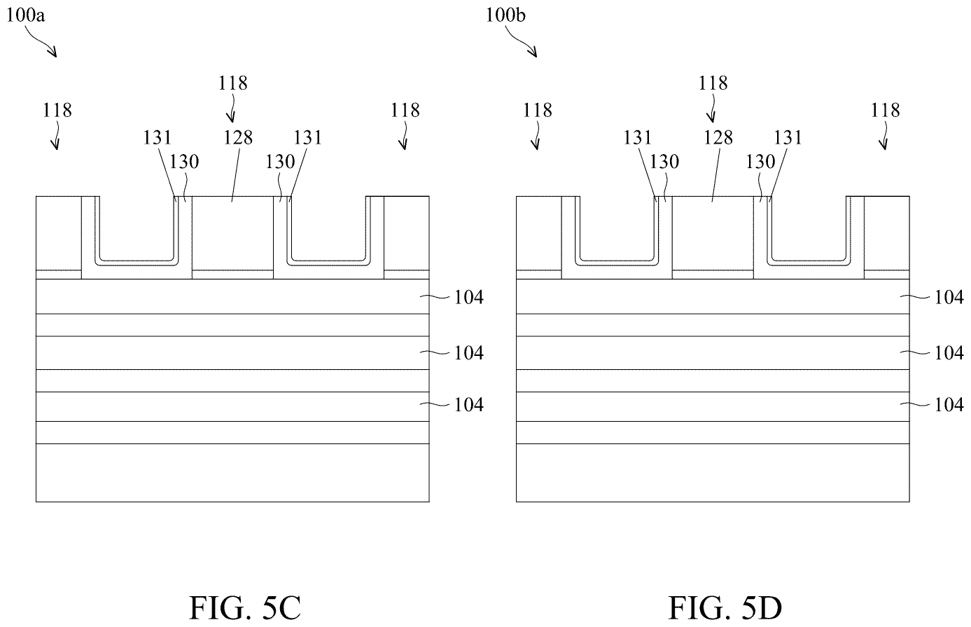

FIGS. 5A-5D illustrate different regions of the integrated circuit 100, in accordance with some embodiments. FIG. 5A illustrates a region 100a of the integrated circuit 100 corresponding to a region at which short channel N-type transistors are formed. FIG. 5B is a cross-sectional view of region 100b corresponding to a region that which short channel P-type transistors are formed. FIG. 5C illustrates a region 100c of the integrated circuit 100 corresponding to a region at which long channel N-type transistors are formed. FIG. 5D illustrates a region 100 D of the integrated circuit 100 corresponding to a region that which long channel P-type transistors are formed. In some embodiments, the channels 105a/b of the regions 100a/b have a length in the X-direction between 20 nm and 30 nm, though other lengths can be utilized without departing from the scope of the present disclosure. In some embodiments, the channels 105c/d of the regions 100c/d have a length in the X-direction that is greater than 30 nm, though other lengths can be utilized without departing from the scope of the present disclosure.

In FIGS. 5A-5D, gate spacer layers 130 have been formed on the sidewalls of the sacrificial gate structures 118. In particular, the gate spacer layers 130 may be formed on sidewalls of the dielectric layer 126 and the sacrificial gate layer 128. The gate spacer layers 130 may also be formed on other exposed surfaces of the integrated circuit. The gate spacer layer 130 can be formed by PVD, CVD, ALD, or other suitable deposition processes. Following formation of the gate spacer layer 130, horizontal portions (e.g., in the X-Y plane) of the gate spacer layer 130 may be removed by an anisotropic etching process, thereby exposing upper surfaces of the fins 112 and the dielectric layer 130. After patterning of the gate spacer layers, vertically thicker portions of the gate spacer layers 130 may remain. The gate spacer layers 130 can include one or more of SiO, SiN, SION, SiCN, SiOCN, SiOC, or other suitable dielectric materials. The gate spacer layers 131 have also been formed on the gate spacer layers 130. The gate spacer layers 131 can include one or more of SiO, SiN, SiON, SiCN, SiOCN, SiOC, or other suitable dielectric materials.

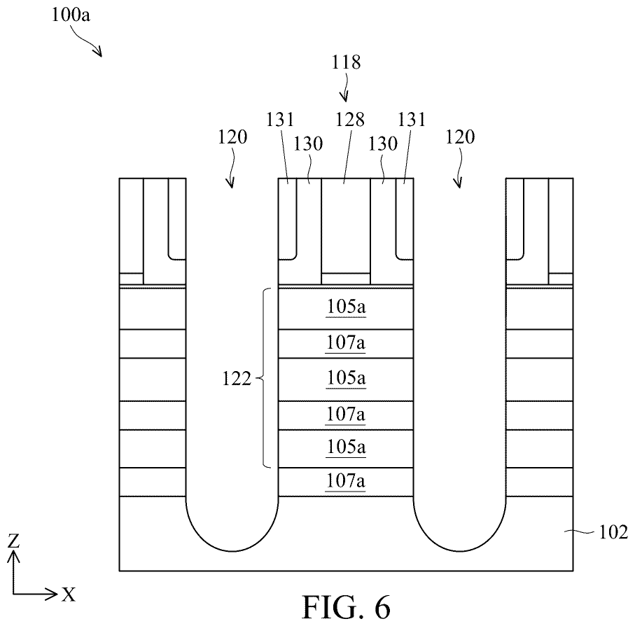

FIG. 6 is a cross-sectional view of the short channel N-type region 100a, in accordance with some embodiments. Though not shown, the process steps shown in FIG. 6 are also performed at the regions 100b-100d.

In FIG. 6, source/drain trenches 120 have been formed, in accordance with some embodiments. After patterning of the gate spacer layers 130, one or more etching processes are performed to form source/drain trenches 120 in the fins 112. Forming the source/drain trenches 120 includes etching through each of the semiconductor layers 104 and sacrificial semiconductor layers 106, and a portion of the substrate 102. Accordingly, the removal operations may include suitable etch operations for removing materials of the semiconductor layers 104, the sacrificial semiconductor layers 106, and the substrate 102. The etching processes can include reactive ion etching (RIE), neutral beam etching (NBE), atomic layer etching (ALE), or the like.

Formation of the source/drain trenches 120 results in formation of stacks 122 of channels 105. In particular, the portions of the semiconductor layers 104 after formation of the source/drain trenches 120 now correspond to channels of a transistor. Formation of the source/drain trenches 120 also results in formation of a plurality of sacrificial semiconductor nanostructures 107 from the sacrificial semiconductor layers 106.

FIG. 6 illustrates a stack 122 of channels 105a interleaved with sacrificial semiconductor nanostructures 107a below the sacrificial gate structure 118 at the region 100a. Though not shown in FIG. 6, the formation of source/drain trenches 120 at the regions 100b-100d results in stacks 122 of channels 105b-105d and sacrificial semiconductor nanostructures 107b-107d at the regions 100b-100d.

Throughout the description, reference numbers may include a suffix “a”, “b”, “c”, or “d”. Use of the suffix “a”, “b”, “c”, or “d” generally indicates a structure in the corresponding region 100a, 100b, 100c, or 100d. For example, channels 105a are formed in the region 100a. Channels 105b are formed in the region 100b. Channels 105c are formed in the region 100c. channels 105d are formed in the region 100d. Throughout the specification, the suffix “a”, “b”, “c”, and “d” may be omitted when description of a structure is general to each of the regions. For example, the channels may be referred to as simply channels 105 without a suffix when description is not particular to any one region.

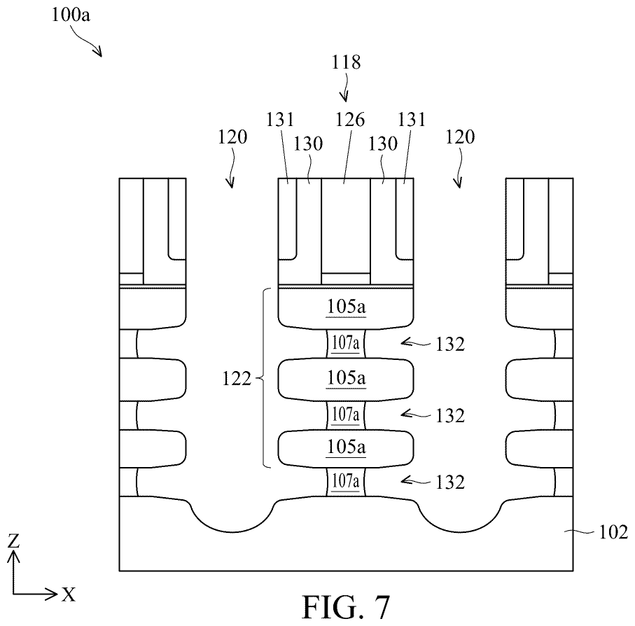

FIG. 7 is a cross-sectional view of the region 100a, in accordance with some embodiments. While only the region 100a is shown in FIG. 7, corresponding processes and structures are utilized at the other regions 100b-d.

In FIG. 7, a selective etching process is performed to recess exposed end portions of the sacrificial semiconductor nanostructures 107 without substantially etching the channels 105. More particularly, recesses 132 are formed in the sacrificial semiconductor nanostructures 107 between adjacent channels 105, or between the lowest channel 105 and the substrate 102. The recesses 132 can be formed by performing an etching process that selectively etches the material of the sacrificial semiconductor nanostructures with respect to the material of the channels 105 and the substrate 102.

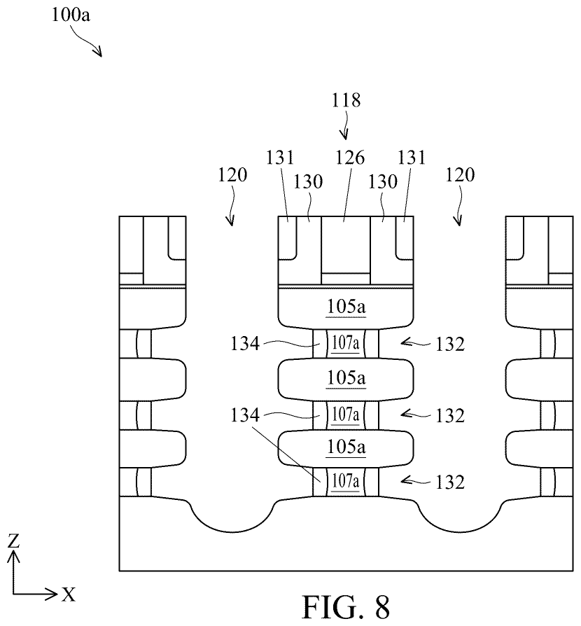

FIG. 8 is a cross-sectional view of the N-type short channel region 100a, in accordance with some embodiments. While only the region 100a is shown in FIG. 8, corresponding processes and structures are utilized at the other regions 100b-d.

In FIG. 8, a dielectric layer has been deposited. The dielectric layer has been deposited in a conformal deposition process lining exposed surfaces of the channels 105, the gate spacer layers 130 and 131, the sacrificial semiconductor nanostructures 107, and the substrate 102. Most notably, the dielectric layer fills the recesses 132. The dielectric layer can include silicon oxide or other suitable dielectric materials. The dielectric layer can be formed by a suitable deposition method such as physical vapor deposition (PVD), CVD, ALD, or the like.

In FIG. 8, dielectric interposers 134 have been formed from the dielectric layer, in accordance with some embodiments. In particular, an etching process has been performed. The etching process removes the dielectric layer except for portions that remain within the recesses 132 abutting the sacrificial semiconductor nanostructures 107. Accordingly, a dielectric interposer 134 is positioned on each end of each sacrificial semiconductor nanostructure 107.

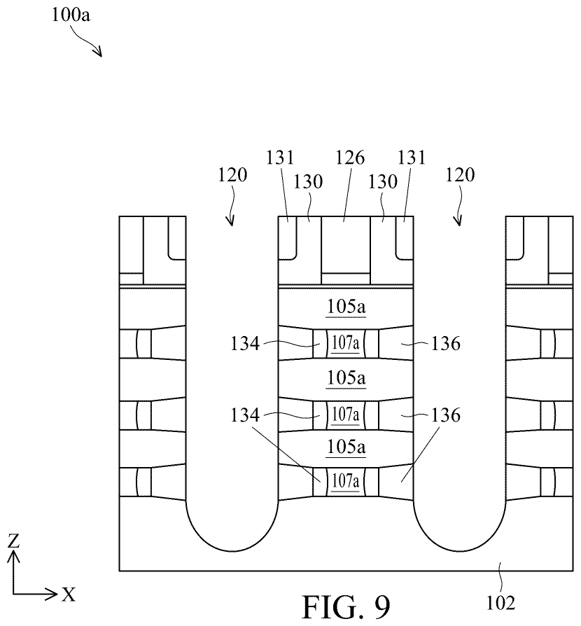

FIG. 9 is a cross-sectional view of the N-type short channel region 100a, in accordance with some embodiments. While only the region 100a is shown in FIG. 9, corresponding processes and structures are utilized at the other regions 100b-d.

In FIG. 9, inner spacers 136 have been formed in the recesses 132 in contact with the dielectric interposers 134, in accordance with some embodiments. The inner spacers 136 are formed by depositing a dielectric material to fill the recesses 132 between the channels 105 and abutting the dielectric interposers 134. Deposition of the dielectric material for the inner spacers 136 may also partially or completely fill the source/drain trenches 120. An etching process, such as an anisotropic etching process, is performed to remove portions of the dielectric material disposed outside the recesses 132. The remaining portions of the dielectric material correspond to the inner spacers 136 shown in FIG. 9. The inner spacer 136 may be a suitable dielectric material, such as silicon carbon nitride (SiCN), silicon oxycarbonitride (SiOCN), or the like, formed by a suitable deposition method such as physical vapor deposition (PVD), CVD, ALD, or the like.

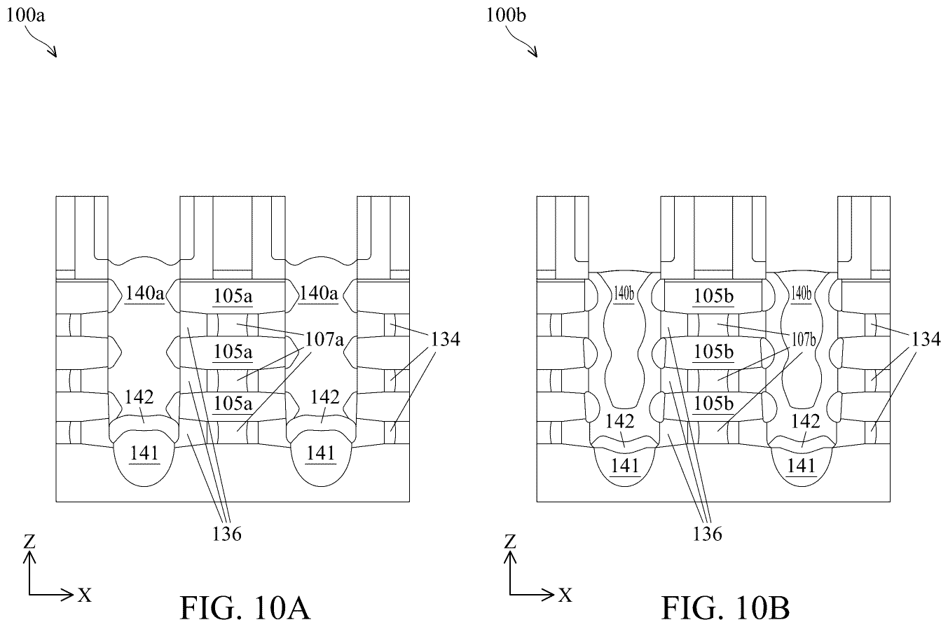

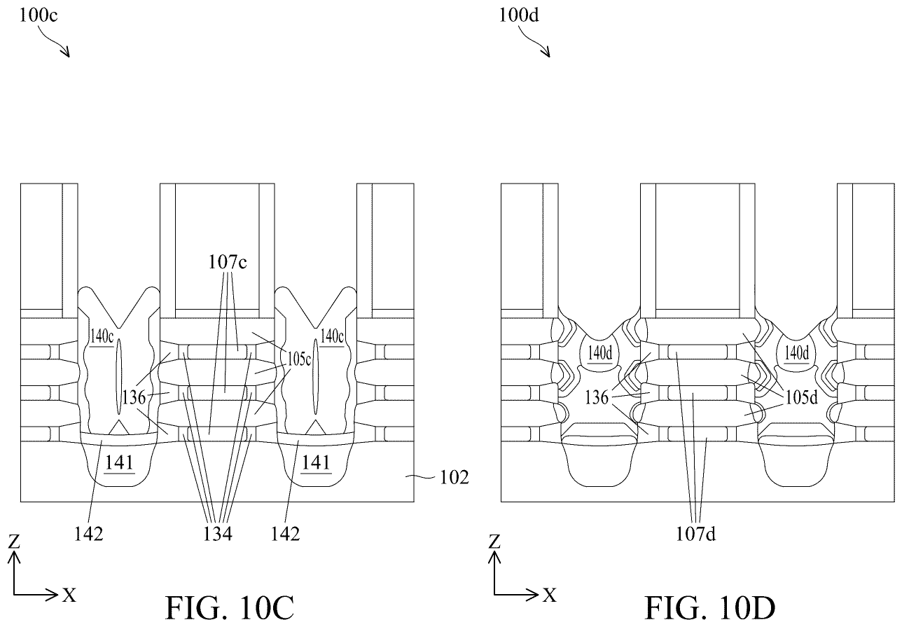

FIGS. 10A-10D are of the integrated circuit regions 100a-100d, in accordance with some embodiments. In FIGS. 10A-10D, a semiconductor layer 141 has been formed at the bottom of each source/drain trench 120 each of the regions 100a-d. In particular, formation of the source/drain regions 120 results in a concave recess being formed in the substrate 102 at the bottom of each source/drain trench 120. The semiconductor layer 141 is formed in the recess at the bottom of each source/drain trench 120 at each of the regions 100a-100d. In some embodiments, the semiconductor layer 141 is an intrinsic (undoped) semiconductor layer. The semiconductor layer 141 can include silicon, silicon germanium, or other suitable semiconductor materials.

In FIGS. 10A-10D, a bottom dielectric structure 142 has been formed on the semiconductor layer 141 at each of the regions 100a-100d. The bottom dielectric layer 142 can provide electrical isolation between the source/drain region 140 (described further below) and the substrate 102. The bottom dielectric structure 142 can include SiN, SiO, SiON, SiCN, SiOCN, SiOC, or other suitable dielectric materials.

In FIGS. 10A-10D, source/drain regions 140 have been formed at each of the regions 100a-100d, in accordance with some embodiments. The source/drain regions 140 are epitaxially grown from the channels 105. The source/drain regions 140 are grown on exposed portions of the fins 112 and contact the channels 105. For each stack 122 of channels 105, there are two source/drain regions 140. Some stacks 122 of channels 105 may share a source/drain 140 with a stack 122 of channels 105 that is adjacent in the X direction.

More particularly, at the short channel N-type region 100a, source/drain regions 140a have been formed, with each channel 105a between two source/drain regions 140a. Sacrificial semiconductor nanostructures 107a are interleaved with the channels 105a. Dielectric interposers 134 are formed on the end of each sacrificial semiconductor nanostructure 107a. Inner spacers 136 fill the remaining portions of the recesses 132. The source/drain region 140a abuts the inner spacers 136. As will be set forth in more detail below, source/drain regions 140a are doped with N-type dopants.

At the short channel P-type region 100b, source/drain regions 140b have been formed, with each channel 105b between two source/drain regions 140b. Sacrificial semiconductor nanostructures 107b are interleaved with the channels 105b. Dielectric interposers 134 are formed on the end of each sacrificial semiconductor nanostructure 107b. Inner spacers 136 fill the remaining portions of the recesses 132. The source/drain region 140b abuts the inner spacers 136. As will be set forth in more detail below, source/drain regions 140b are doped with P-type dopants.

At the long channel N-type region 100c, source/drain regions 140c have been formed, with each channel 105c between two source/drain regions 140c. Sacrificial semiconductor nanostructures 107c are interleaved with the channels 105c. Dielectric interposers 134 are formed on the end of each sacrificial semiconductor nanostructure 107c. Inner spacers 136 fill the remaining portions of the recesses 132. The source/drain region 140c abuts the inner spacers 136. As will be set forth in more detail below, source/drain regions 140c are doped with N-type dopants.

At the long channel P-type region 100d, source/drain regions 140d have been formed, with each channel 105d between two source/drain regions 140d. Sacrificial semiconductor nanostructures 107d are interleaved with the channels 105d. Dielectric interposers 134 are formed on the end of each sacrificial semiconductor nanostructure 107d. Inner spacers 136 fill the remaining portions of the recesses 132. The source/drain region 140d abuts the inner spacers 136. As will be set forth in more detail below, source/drain regions 140d are doped with P-type dopants.

The source/drain regions 140a-d may include any acceptable material, such as appropriate for N-type or P-type devices. For N-type regions 100a and 100c, the source/drain regions 140a/c include materials exerting a tensile strain in the channel regions, such as silicon, SiC, SiCP, SiP, or the like, in some embodiments. For the P-type regions 100b/d, the source/drain regions 140b/d include materials exerting a compressive strain in the channel regions, such as SiGe, SiGeB, Ge, GeSn, or the like, in accordance with certain embodiments. The source/drain regions 140 may have surfaces raised from respective surfaces of the fins and may have facets. Neighboring source/drain regions 140 may merge in some embodiments to form a singular source/drain region 140 over two neighboring fins of the fins 112.

In some embodiments, the N-type source/drain regions 140a/c are formed in a same processing step. The N-type source/drain regions 140a/c can be formed in multiple epitaxial growth processes. A first epitaxial growth process may form intrinsic semiconductor extensions from the channels 105a/c. A second epitaxial growth process may then be performed to fill the source/drain trenches 120 with the source/drain regions 140a/c. An in situ doping process may be performed during formation of the source/drain regions 140a/c to implant to the source/drain regions 140a/c with N-type dopants. The N-type dopants can include phosphorus, arsenic, antimony, or other suitable N-type dopants species. In some embodiments, different epitaxial growth processes can be utilized to form the source/drain regions 140a/c. In some embodiments, a gap or void is formed at the interface between the source/drain region 140c and the bottom dielectric layer 142 due to the larger width of the source/drain trenches 120 at the region 100c. The P-type regions 100b/d may be masked during formation of the source/drain regions 140a/c at the N-type regions 100a/c.

In some embodiments, the P-type source/drain regions 140b/d are formed in a same processing step. The P-type source/drain regions 140b/d can be formed in multiple epitaxial growth processes. A first epitaxial growth process may form intrinsic semiconductor extensions from the channels 105b/d. A second epitaxial growth process may then be performed to fill the source/drain trenches 120 with the source/drain regions 140b/d. An in-situ doping process may be performed during formation of the source/drain regions 140b/d to implant to the source/drain regions 140b/d with P-type dopants. The P-type dopants can include boron, gallium, indium, or other suitable P-type dopants species. In some embodiments, different epitaxial growth processes can be utilized to form the source/drain regions 140b/d. The N-type regions 100a/c may be masked during formation of the source/drain regions 140b/d at the P-type regions 100a/c.

The source/drain regions 140 may be implanted with dopants followed by an annealing process. The source/drain regions 140 may have an impurity concentration of between about 1019 cm⁻³ and about 1021 cm^{'3}. N-type and/or P-type impurities for source/drain regions 140 may be any of the impurities previously discussed. In some embodiments, the source/drain regions 140 are in situ doped during growth.

As described previously, the sacrificial semiconductor nanostructures 107 have been utilized as an interposer interleaved with the channels 105. In P-type regions, it is possible that the use of sacrificial semiconductor nanostructures alone can result in degradation of P-type transistors. Furthermore, there is the risk of co-diffusion. One possible solution is to utilize a dielectric interposer instead of a sacrificial semiconductor nanostructure interposer. However, this also comes with risks and drawbacks. For example, upon removal of the dielectric interposers to release the channels, there can be damage to the trench isolation regions and interlevel dielectric layers (described further below).

To overcome at least some of the drawbacks of other solutions, a combination of sacrificial semiconductor nanostructures 107 and dielectric interposers 134 have been utilized, in accordance with some embodiments. In particular, the sacrificial semiconductor nanostructures 107 are partially removed and partially replaced with a dielectric interposer 134. The dielectric interposers 134 are partially removed and inner spacers 136 are formed to fill the remaining portions of the recesses 132, as described previously. The use of both sacrificial semiconductor nanostructures 107 and dielectric interposers 134 results in benefits to both P-type regions 100b/d and N-type regions 100a/c. In particular, this can provide the full dielectric interposer and stress benefits for the P-type regions. This also can provide some beneficial tensile stress in the N-type regions provided by use of the sacrificial semiconductor nanostructures 107. Accordingly, both P-type regions and N-type regions benefit from the combination of sacrificial semiconductor nanostructures 107 and dielectric interposers 134. Furthermore, there is a small amount of dialectic recess for the shorter, devices without excessive oxide removal upon replacement of the sacrificial gate structures 118. This avoids filled damage and improves wafer yields.

In one example, the sacrificial semiconductor nanostructures 107 are silicon germanium and the dielectric interposers 134 are silicon oxide, though other materials can be utilized without departing from the scope of the present disclosure.

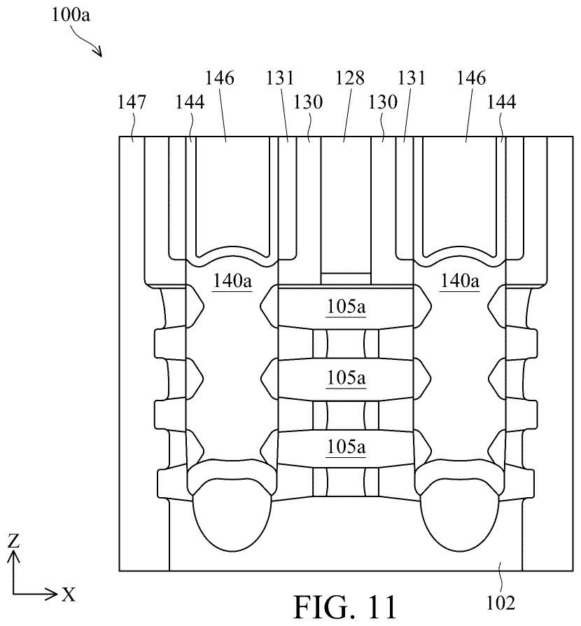

FIG. 11 is a cross-sectional view of the N-type short channel region 100a, in accordance with some embodiments. While only the region 100a is shown in FIG. 11, corresponding processes and structures are utilized that the other regions 100b-d.

In FIG. 11, a contact etch stop layer (CESL) 144 and an interlayer dielectric (ILD) 146 have been formed, in accordance with some embodiments. The CESL layer 144 can include a thin dielectric layer conformally deposited on exposed surfaces of the source/drain regions 140, the gate spacer layers 131, and on other exposed surfaces. The CESL layer 144 can include SiN, SiC, SiOC, SiOCN, SiON, or other suitable dielectric materials. The CESL 144 can be deposited by CVD, ALD, PVD, or other suitable deposition processes.

The interlevel dielectric layer 146 covers the CESL 144. The interlevel dielectric layer 146 fills the remaining spaces between adjacent sacrificial gate structures 118. Interlevel dielectric layer 146 may correspond to a lowest interlevel dielectric layer of the integrated circuit 100. In some embodiments, the interlevel dielectric layer 146 may be termed ILDO. Though not shown herein, additional interlevel dielectric layers may be formed over the interlevel dielectric layer 146. A network of conductive vias and metal lines may be formed in the upper interlevel dielectric layers. The interlevel dielectric layer 146 can include SiO, SiON, SiN, SiC, SiOC, SiOCN, SiON, or other suitable dielectric materials. The interlevel dielectric layer 146 can be deposited by CVD, ALD, PVD, or other suitable deposition processes.

In some embodiments, a CMP process is performed after deposition of the interlevel dielectric layer 146. The result of the CMP process is that the top surfaces of the interlevel dielectric layer 146, the CESL layer 144, the gate spacer layer 130, and the sacrificial gate layer 128 are coplanar. The CMP process may also reduce the height of the sacrificial gate structures 118.

In some embodiments, dielectric isolation structures 147 are also formed adjacent to the source/drain regions 140. The dielectric isolation structures 147 can include SiN, SiO, SiC, SiOC, SiOCN, SiON, or other suitable dielectric materials.

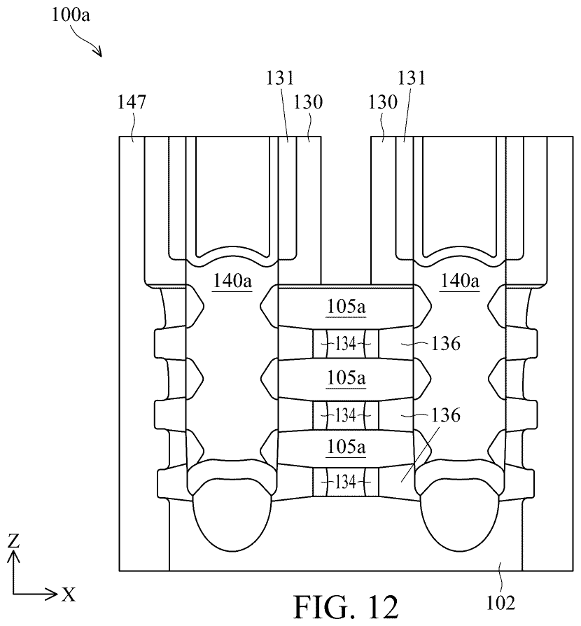

FIG. 12 is a cross-sectional view of the N-type short channel region 100a, in accordance with some embodiments. While only the region 100a is shown in FIG. 12, corresponding processes and structures are utilized that the other regions 100b-d.

In FIG. 12, the sacrificial gate structures 118 and the sacrificial semiconductor nanostructures 107 are removed, in accordance with some embodiments. The sacrificial gate structures 118 can be removed by using an etching process that selectively etches the material of the sacrificial gate structure 118 with respect to the material of the channels 107 and on other exposed surfaces. The sacrificial semiconductor nanostructures 107 can be removed by a selective etching process using an etchant that is selective to the material of the sacrificial semiconductor nanostructures 107, such that the sacrificial semiconductor nanostructures 107 are removed without substantially etching the channels 105. In some embodiments, the etching process is an isotropic etching process using an etching gas, and optionally, a carrier gas, where the etching gas comprises F₂ and HF, and the carrier gas may be an inert gas such as Ar, He, N₂, combinations thereof, or the like.

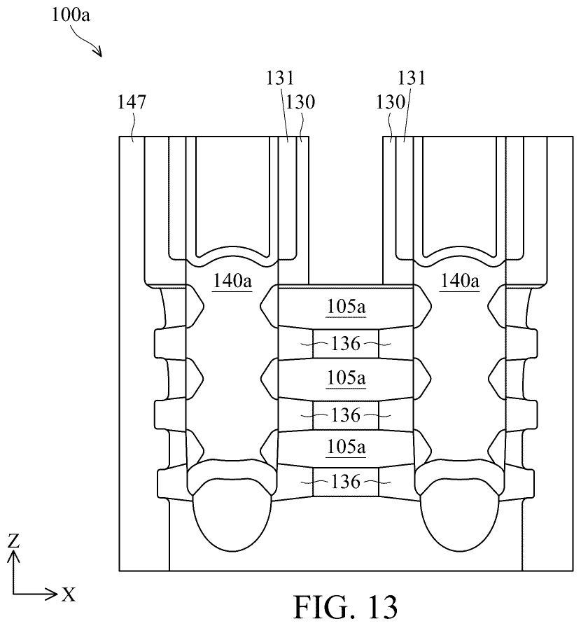

FIG. 13 is a cross-sectional view of the N-type short channel region 100a, in accordance with some embodiments. While only the region 100a is shown in FIG. 13, corresponding processes and structures are utilized at the other regions 100b-d.

FIG. 13, release of the channels 105 is completed by removal of the dielectric interposers 134. The dielectric interposers 134 are removed by an etching process that selectively etches the material of the dielectric interposers 134 with respect to the channels 105 and the inner spacers 136. As described previously, removal of the dielectric interposers 134 may also remove some material of the interlevel dielectric layer 146 and the trench isolation regions 116. However, because the dielectric interposers 134 are relatively thin and only occupy a portion of the space around the channels 105, the etching process to remove the dielectric interposers 134 can be performed quickly and without substantially removing material from the interlevel dielectric layer 146 and the trench isolation regions 116. Removal of the sacrificial gate structure 118, the sacrificial semiconductor nanostructures 107, and the dielectric interposers 134, results in the formation of voids between the channels 105.

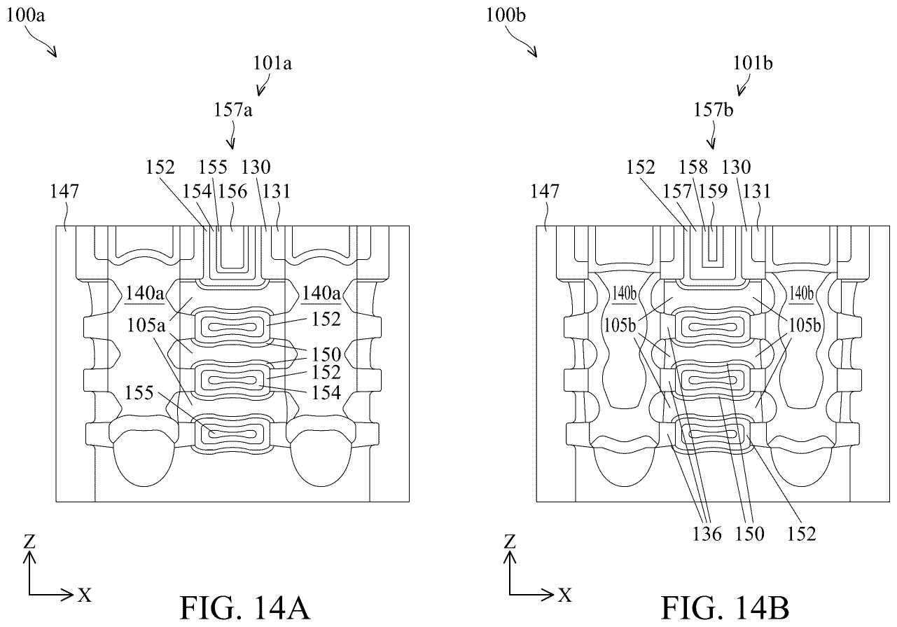

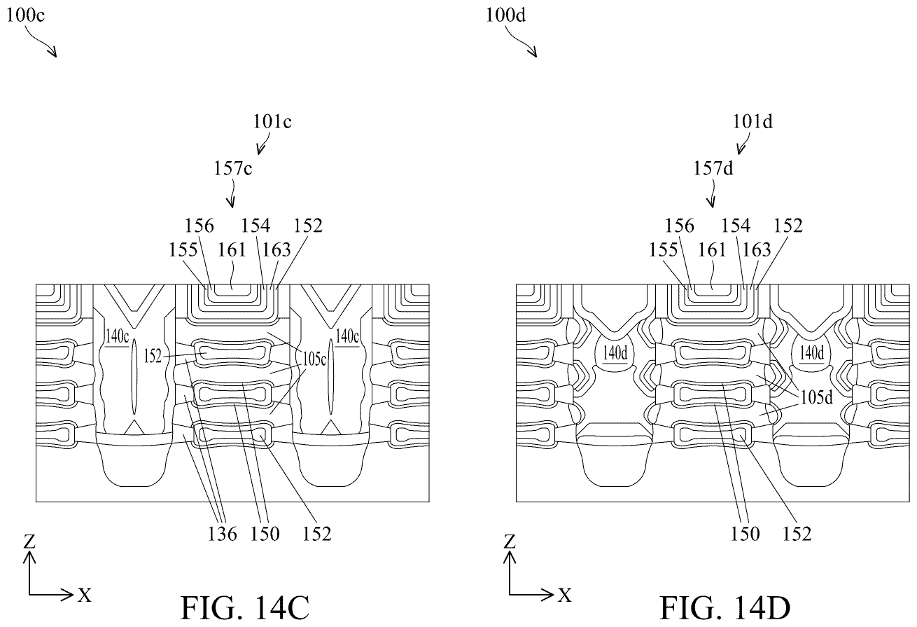

FIGS. 14A-14D are of the integrated circuit regions 100a-100d, in accordance with some embodiments. In FIGS. 10A-10D, gate dielectric layers and gate metals are formed at each of the regions 100a-100d, in accordance with some embodiments. This substantially completes formation of the transistors 101. In particular, a short channel N-type transistor 101a is formed at the region 100a. A short channel P-type transistor 101b is formed at the region 100b. A long channel N-type transistor 101c is formed at the region 100c. And they long channel P-type transistor 101d is formed at the region 100d. As will be set forth in more detail below, different combinations of gate metals may be used at each of the transistors 101a-d.

In FIGS. 14A-D, a gate dielectric including an interfacial gate dielectric layer 150 and a high-K gate dielectric layer 152 has been deposited. The interfacial gate dielectric layer 150 has been deposited on exposed portions of the channels 105 and sidewall spacers 130, in accordance with some embodiments. The interfacial gate dielectric layer 150 forms directly on the exposed portions of the channels 105. The high-K gate dielectric layer 152 forms on the interfacial gate dielectric layer 150 and on other exposed surfaces, such as the exposed sidewalls of the gate spacer layers 130.

The interfacial gate dielectric layer 150 is wrapped around the channels 105. The interfacial gate dielectric layer 150 can include a dielectric material such as silicon oxide, silicon nitride, or other suitable dielectric materials. The interfacial gate dielectric layer 150 can include a comparatively low-K dielectric with respect to high-K dielectric such as hafnium oxide or other high-K dielectric materials that may be used in gate dielectrics of transistors. High-K dielectrics can include dielectric materials with a dielectric constant higher than the dielectric constant of silicon oxide. The interfacial gate dielectric layer 150 can be formed by a thermal oxidation process, a chemical vapor deposition (CVD) process, or an atomic layer deposition (ALD) process. The interfacial gate dielectric layer 150 can have a thickness between 0.5 nm and 2 nm. Other materials, deposition processes, and thicknesses can be utilized for the interfacial gate dielectric layer 150 without departing from the scope of the present disclosure.

The high-K gate dielectric layer 152 is deposited in a conformal deposition process. The conformal deposition process deposits the high-K gate dielectric layer 152 on the interfacial gate dielectric layer 150, on the substrate 102, on the trench isolation regions 116, and on the gate spacer layers 130. The high-K gate dielectric layer 152 is wrapped around the channels 105. The high-K gate dielectric layer 152 has a thickness between 1 nm and 3 nm. The high-K dielectric layer includes one or more layers of a dielectric material, such as HfO₂, HfSiO, HfSION, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The high-K gate dielectric layer 152 may be formed by CVD, ALD, or any suitable method. Other thicknesses, deposition processes, and materials can be utilized for the high-K gate dielectric layer 152 without departing from the scope of the present disclosure.

In FIG. 14A, a gate metal 154, a gate metal 155, and a gate metal 156 have been deposited to form the gate electrode 157a of the transistor 101a. The gate metal 154 is deposited on all exposed surfaces of the high-K gate dielectric layer 152. The gate metal 155 is deposited on the gate metal 154. The gate metal 155 is formed on the gate metal 154. The gate metal 156 has been formed on the gate metal 155. The gate metal 156 may correspond to a gate fill material that fills all remaining space previously occupied by the sacrificial gate layer 128 and the sacrificial semiconductor nanostructures 107a. The gate metals 154 and 155 are wrapped around the channels 105a. In some embodiments, the gate metal 156 may also wrap around the channels 105a, depending on the thickness of previous gate metals and the vertical distance between adjacent channels 105a.

In some embodiments, the gate metal 154 corresponds to a work function layer selected to impart a particular threshold voltage to the corresponding transistors. The work function layer 154 can include titanium nitride, tantalum nitride, or other suitable conductive materials. The gate metal 155 can include one or more of Ti, TiN, Ta, TaN, Al, Cu, Co, Ru, W, Au, or other suitable conductive materials. The gate metal 156 can include one or more of Ti, TiN, Ta, TaN, Al, Cu, Co, Ru, W, Au, or other suitable conductive materials. The gate metals 154, 155, and 156 can be deposited by PVD, ALD, or CVD. Other configurations, materials, and deposition processes can be utilized for the gate metals 154, 155, and 156 without departing from the scope of the present disclosure. In some embodiments, only a single gate metal is utilized. In some embodiments, different numbers of gate metals are utilized. In practice, the gate metals can include one or more conductive liner layers, work function layers, and gate fill layers that collectively make up the gate metal.

In FIG. 14B, a gate metal 157, a gate metal 158, and a gate metal 159 have been deposited to form the gate electrode 157b of the transistor 101b. The gate metal 157 is deposited on all exposed surfaces of the high-K gate dielectric layer 152. The gate metal 158 is deposited on the gate metal 157. The gate metal 159 has been formed on the gate metal 158. The gate metal 159 may correspond to a gate fill material that fills all remaining space previously occupied by the sacrificial gate layer 128 and the sacrificial semiconductor nanostructures 107a. The gate metal 157 is wrapped around the channels 105b. In some embodiments, the gate metals 158 and 159 may also wrap around the channels 105b, depending on the thickness of previous gate metals and the vertical distance between adjacent channels 105b.

In some embodiments, the gate metal 157 corresponds to a work function layer selected to impart a particular threshold voltage to the corresponding transistors. The work function layer 157 can include titanium nitride, tantalum nitride, or other suitable conductive materials. The gate metal 158 can include one or more of Ti, TiN, Ta, TaN, Al, Cu, Co, Ru, W, Au, or other suitable conductive materials. The gate metal 159 can include one or more of Ti, TiN, Ta, TaN, Al, Cu, Co, Ru, W, Au, or other suitable conductive materials. The gate metals 157, 158, and 159 can be deposited by PVD, ALD, or CVD. Other configurations, materials, and deposition processes can be utilized for the gate metals 157, 158, and 159 without departing from the scope of the present disclosure. In some embodiments, only a single gate metal is utilized. In some embodiments, different numbers of gate metals are utilized. In practice, the gate metals can include one or more conductive liner layers, work function layers, and gate fill layers that collectively make up the gate metal.

In FIG. 14C, a gate metal 161, a gate metal 163, the gate metal 154, the gate metal 155, and the gate metal 156 have been deposited to form the gate electrode 157c of the transistor 101c. The gate metal 163 is deposited on all exposed surfaces of the high-K gate dielectric layer 152. The gate metal 154 is deposited on the gate metal 154. The gate metal 155 is deposited on the gate metal 154. The gate metal 155 is formed on the gate metal 154. The gate metal 156 has been formed on the gate metal 155. The gate metal 161 is formed on the gate metal 156. The gate metal 161 may correspond to a gate fill material that fills all remaining space previously occupied by the sacrificial gate layer 128 and the sacrificial semiconductor nanostructures 107c. The gate metal 163 is wrapped around the channels 105c. In some embodiments, one or more other gate metals may also wrap around the channels 105c, depending on the thickness of previous gate metals and the vertical distance between adjacent channels 105c.

In some embodiments, the gate metal 163 corresponds to a work function layer selected to impart a particular threshold voltage to the corresponding transistors. The work function layer 163 can include titanium nitride, tantalum nitride, or other suitable conductive materials. The gate metal 161 can include one or more of Ti, TiN, Ta, TaN, Al, Cu, Co, Ru, W, Au, or other suitable conductive materials. The gate metals 163 and 161 can be deposited by PVD, ALD, or CVD. Other configurations, materials, and deposition processes can be utilized for the gate metals of the gate electrode 157c without departing from the scope of the present disclosure. In some embodiments, only a single gate metal is utilized. In some embodiments, different numbers of gate metals are utilized. In practice, the gate metals can include one or more conductive liner layers, work function layers, and gate fill layers that collectively make up the gate metal.

In FIG. 14D, the gate metal 161, the gate metal 163, the gate metal 154, the gate metal 155, and the gate metal 156 have been deposited to form the gate electrode 157d of the transistor 101d. The gate metal 163 is deposited on all exposed surfaces of the high-K gate dielectric layer 152. The gate metal 154 is deposited on the gate metal 154. The gate metal 155 is deposited on the gate metal 154. The gate metal 155 is formed on the gate metal 154. The gate metal 156 has been formed on the gate metal 155. The gate metal 161 is formed on the gate metal 156. The gate metal 161 may correspond to a gate fill material that fills all remaining space previously occupied by the sacrificial gate layer 128 and the sacrificial semiconductor nanostructures 107d. The gate metal 163 is wrapped around the channels 105d. In some embodiments, one or more other gate metals may also wrap around the channels 105d, depending on the thickness of previous gate metals and the vertical distance between adjacent channels 105d.

In some embodiments, the gate metal 163 corresponds to a work function layer selected to impart a particular threshold voltage to the corresponding transistors. The work function layer 163 can include titanium nitride, tantalum nitride, or other suitable conductive materials. The gate metal 161 can include one or more of Ti, TiN, Ta, TaN, Al, Cu, Co, Ru, W, Au, or other suitable conductive materials. The gate metals 163 and 161 can be deposited by PVD, ALD, or CVD. Other configurations, materials, and deposition processes can be utilized for the gate metals of the gate electrode 157c without departing from the scope of the present disclosure. In some embodiments, only a single gate metal is utilized. In some embodiments, different numbers of gate metals are utilized. In practice, the gate metals can include one or more conductive liner layers, work function layers, and gate fill layers that collectively make up the gate metal.

While FIGS. 14A-14D illustrate a plurality of gate metals in each transistor 101, in practice, only a single gate metal may be present in some embodiments. More or fewer gate metals can be utilized without departing from the present disclosure.

Though not shown in FIGS. 14A-14D, source/drain contacts may also be formed in contact with the source/drain regions. A silicide may be formed on the source/drain region 140, with a source/drain contact metal formed on top of the silicide. The source/drain regions 140a-d are shown with various shapes and layers. The source/drain regions can have various other shapes and layers without departing from the scope of the present disclosure. Furthermore, the silicide and source/drain contacts may have various shapes and configurations based, in part, on the shapes and configurations of the source/drain regions 140.

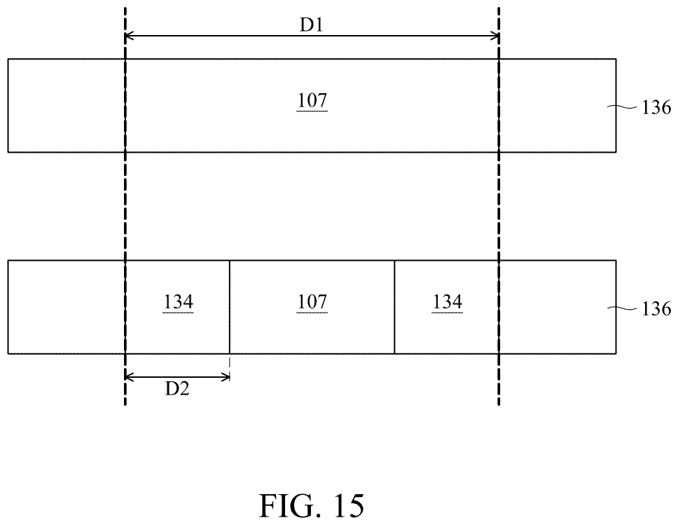

FIG. 15 is a cross-sectional view illustrating a first interposer structure including only a sacrificial nanostructure 107, and a second interposer structure including both the sacrificial semiconductor nanostructure 107 and dielectric interposers 134, in accordance with some embodiments. Inner spacers 136 are shown on the ends. The dimension D1 corresponds to an entire length of the interposer in the X direction and may have a value between 5 nm and 30 nm, though other values can be utilized without departing from the scope of the present disclosure. The dimension D2 corresponds to the width in the X direction of an individual dielectric interposer 134. The dimension D2 can have a value between one nanometer and 10 nm, though other values can be utilized without departing from the scope of the present disclosure. In some embodiments, the ratio of D2 to D1 is between 30 and 2, though other values can be utilized without departing from the scope of the present disclosure.

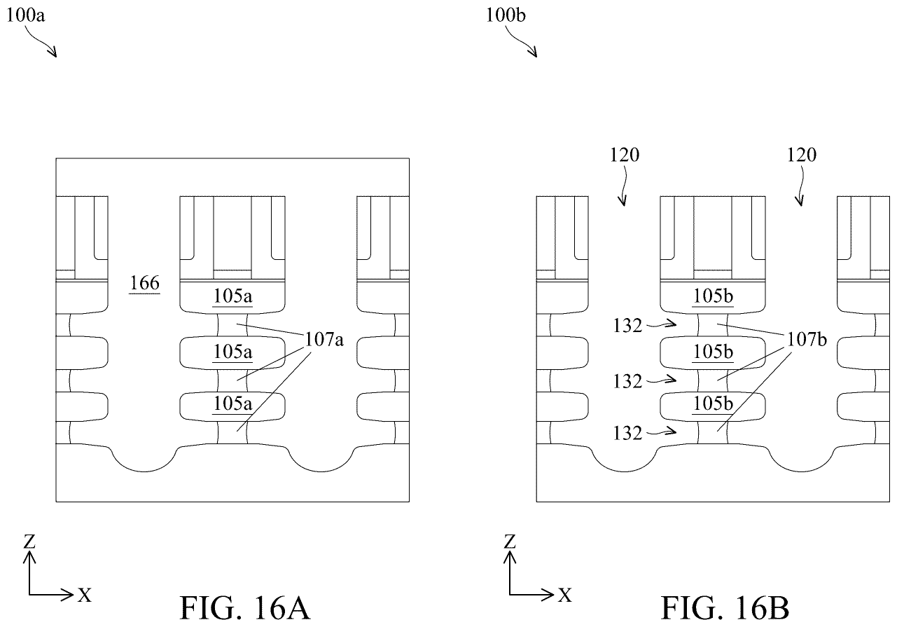

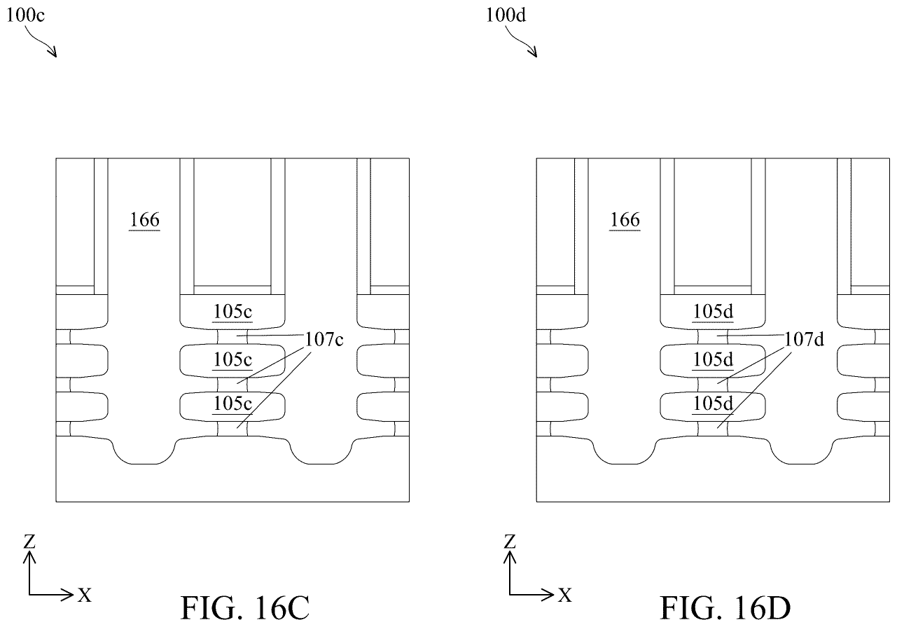

FIGS. 16A-26D are cross-sectional views of an integrated circuit 100 at various stages of processing, in accordance with some embodiments.

FIGS. 16A-16D illustrate the regions 100a-d, as described previously, in accordance with some embodiments. The stage of processing shown in FIGS. 16A-16D corresponds substantially to the stage of processing shown in FIG. 7. However, differently from FIG. 7, a mask 166 has been formed in the source/drain trenches 120 of the regions 100a, 100c, and 100d. The mask 166 is not present at the source/drain trenches 120 of the short channel P-type region 100b. Accordingly, the channels 105b are exposed at the region 100b. The mask 166 can include one or more of a photoresist, a dielectric layer, a ceramic layer, or a conductive layer.

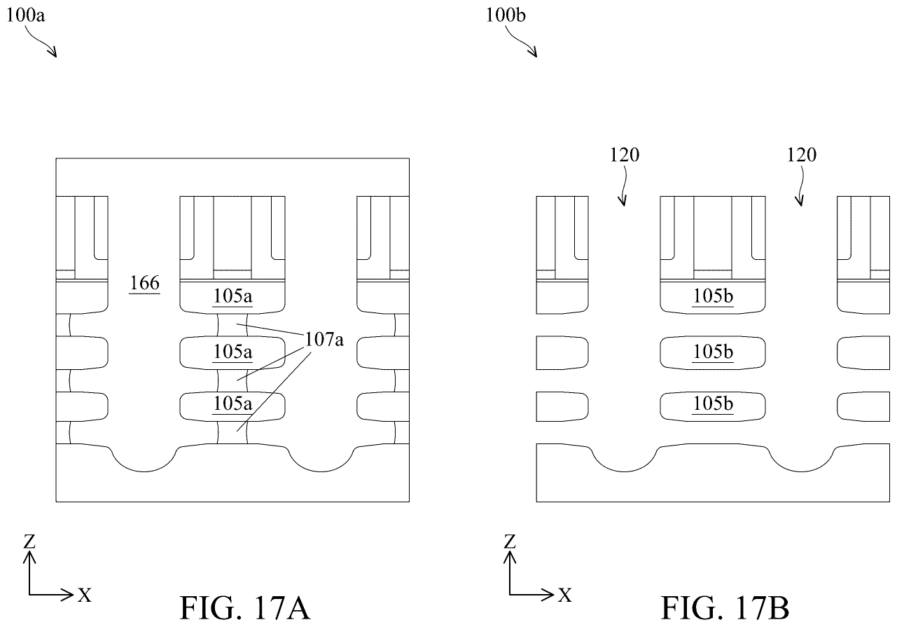

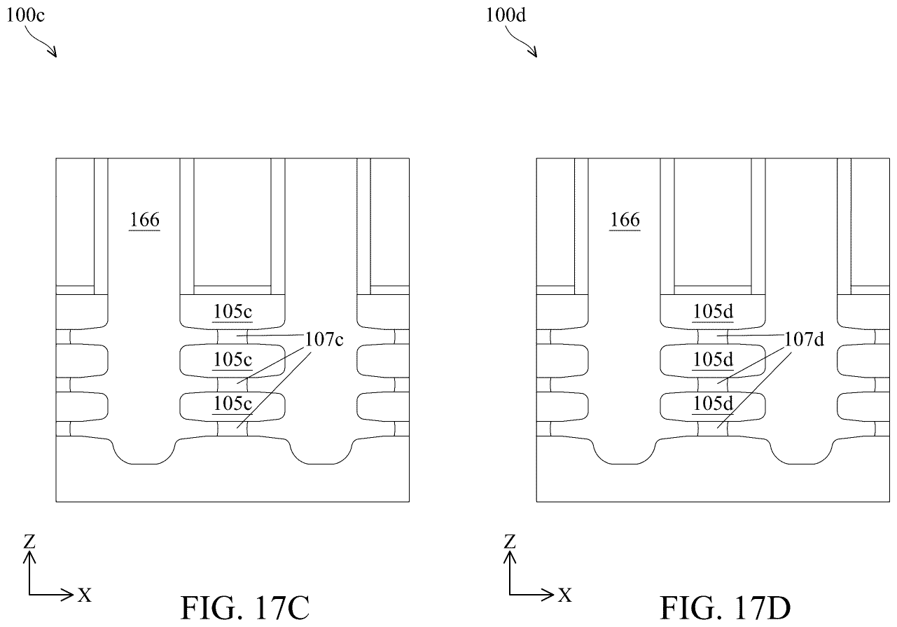

FIGS. 17A-17D illustrate the regions 100a-d, in accordance with some embodiments. In FIGS. 17A-17D, the mask 166 remains at the regions 100a, 100c, and 100d. At the region 100b, a further etching process has been performed to completely remove the sacrificial semiconductor nanostructures 107b at the region 100b. The sacrificial semiconductor nanostructures 107a, 107c, and 107d are protected from the etching process by the mask 166.

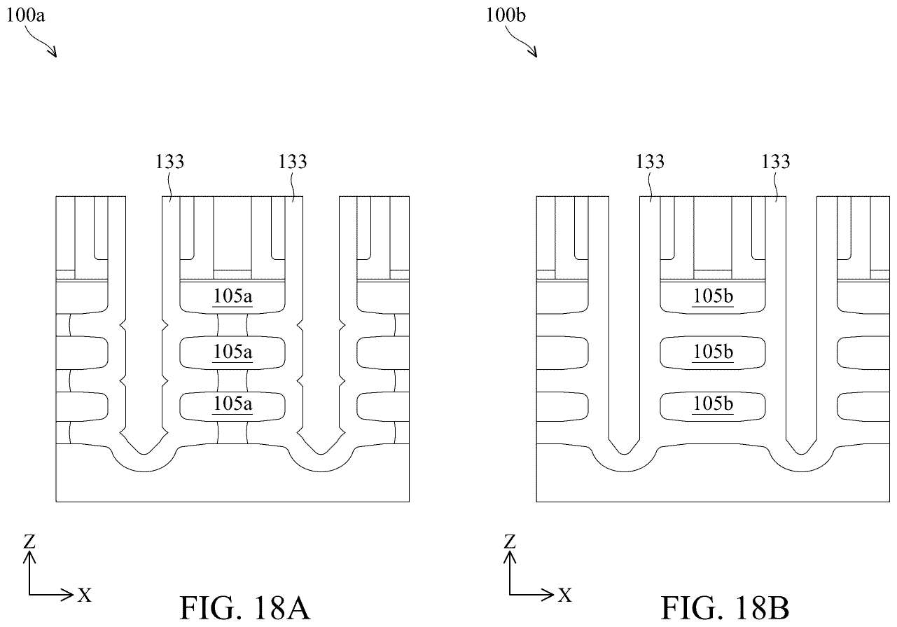

FIGS. 18A-18B illustrate the regions 100a-b, in accordance with some embodiments. For simplicity, the regions 100c and 100d are not illustrated. However, the structure of the regions 100a will be substantially similar to the structures of the regions 100c and 100d at the stage of processing shown in FIG. 18A. In FIGS. 18A-18B, the mask 166 has been removed. A dielectric layer 133 for forming the dielectric interposers 134 has been deposited, substantially as described in relation to FIG. 8, in accordance with some embodiments. Because the sacrificial semiconductor nanostructures 107b have been entirely removed at the region 100b, the dielectric layer 133 entirely fills the space between the channels 105b. The dielectric layer 133 fills the recesses 132 at the region 100a.

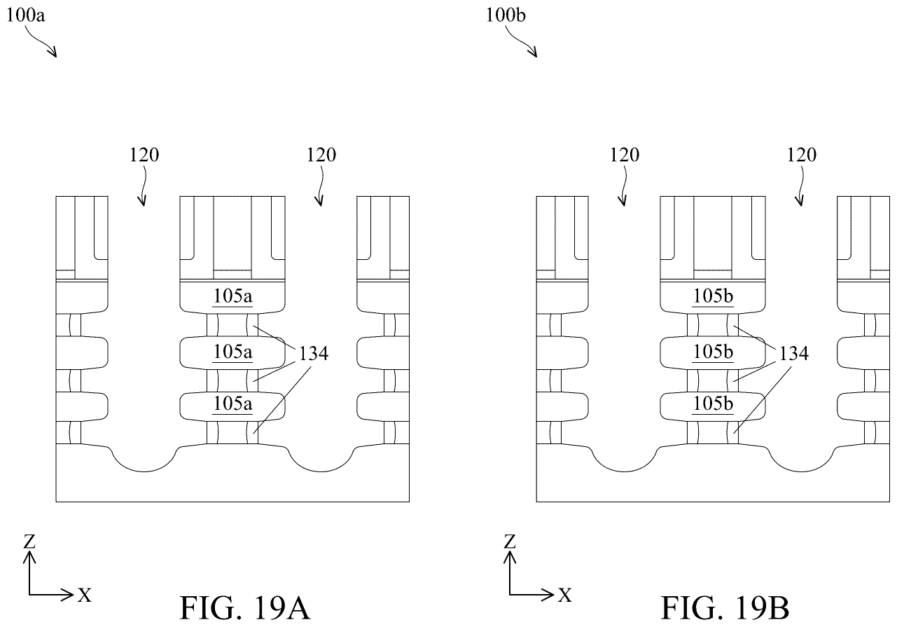

FIGS. 19A-19B illustrate the regions 100a-b, in accordance with some embodiments. For simplicity, the regions 100c and 100d are not illustrated. However, the structure of the regions 100a will be substantially similar to the structures of the regions 100c and 100d at the stage of processing shown in FIG. 19A. In FIGS. 19A and 19B, the dielectric interposers 134 have been formed from the dielectric layer 133. At the region 100a, the dielectric interposers 134 are formed on ends of the sacrificial semiconductor nanostructures 107a. At the region 100b, the dielectric interposers 134 completely fill the space previously occupied by the sacrificial semiconductor nanostructures 107b. The recessing process has been performed substantially as described in relation to FIG. 8.

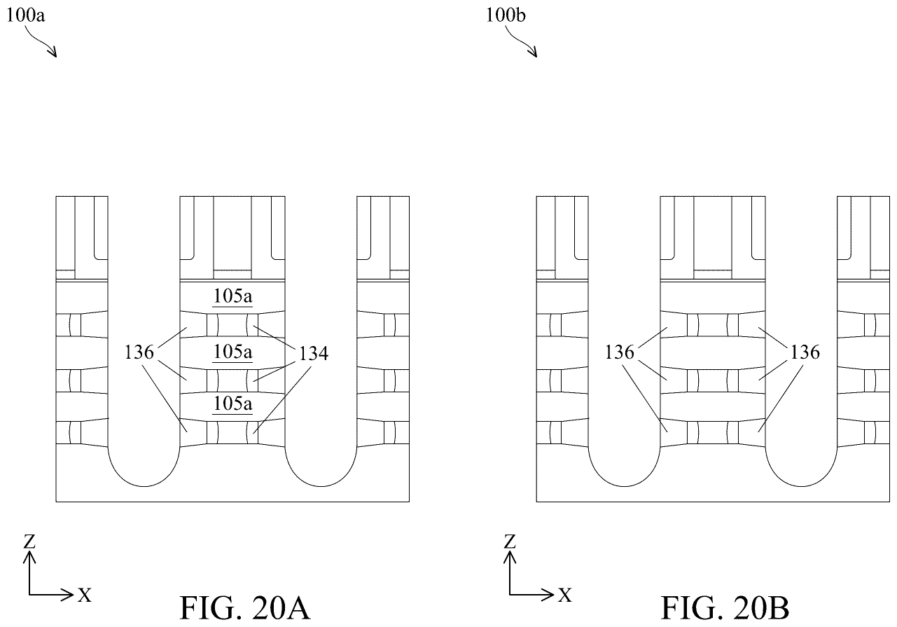

FIGS. 20A-20B illustrate the regions 100a-b, in accordance with some embodiments. For simplicity, the regions 100c and 100d are not illustrated. However, the structure of the regions 100a will be substantially similar to the structures of the regions 100c and 100d at the stage of processing shown in FIG. 20A. In FIGS. 20A and 20B, inner spacers 136 have been formed in contact with the dielectric interposers 134 substantially as described in relation to FIG. 9.

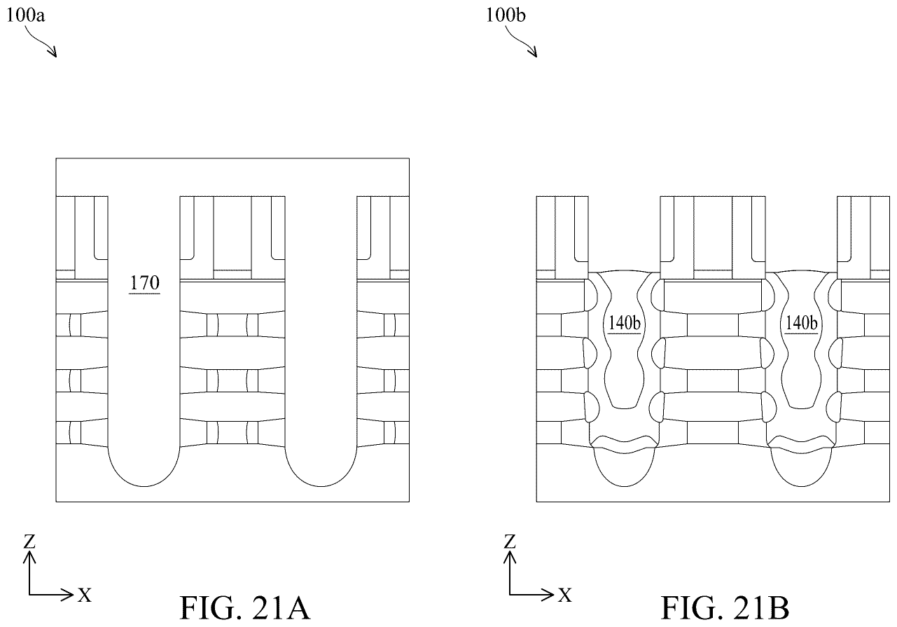

FIGS. 21A-21B illustrate the regions 100a-b, in accordance with some embodiments. For simplicity, the regions 100c and 100d are not illustrated. However, the structure of the regions 100a will be substantially similar to the structures of the region 100c, while the structures of the region 100d will be substantially similar to the structures of the region 100b. In FIG. 21A, a mask 170 has been formed in the source/drain trenches 120 at the region 100a (and at the region 100c). In FIG. 21B, the semiconductor layer 141, the bottom dielectric layer 142, and the P-type source/drain regions 140b have been formed (P-type source/drain regions 140d are also formed at the region 100d), substantially as described in relation to FIG. 10B. Because the sacrificial semiconductor nanostructures 107b have been removed at the short channel P-type region 100b, the P-type transistors 101b gain the full benefit of utilizing the dielectric interposers 134 without the drawbacks of utilizing the sacrificial semiconductor nanostructures 107b.

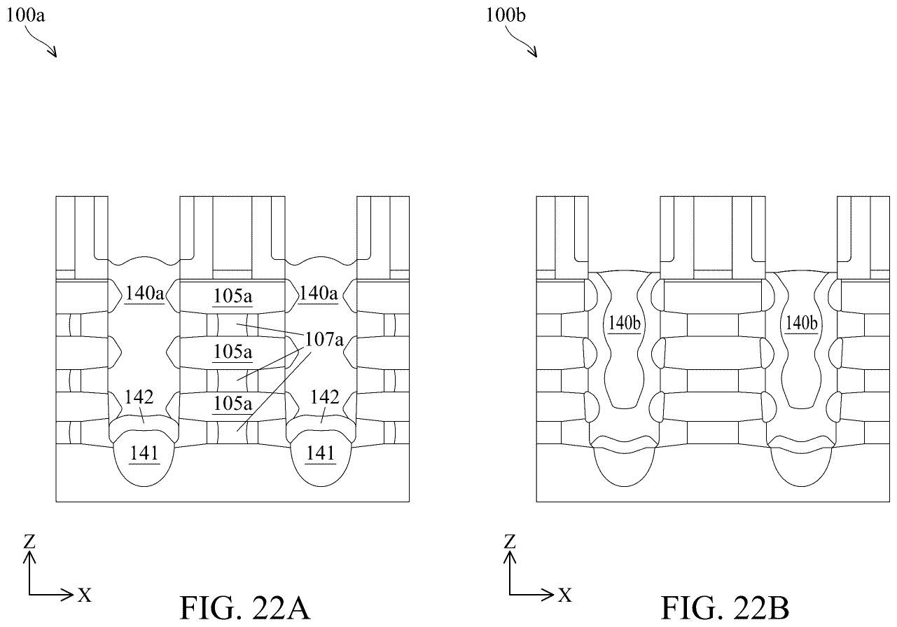

FIGS. 22A-22B illustrate the regions 100a-b, in accordance with some embodiments. For simplicity, the regions 100c and 100d are not illustrated. However, the structure of the regions 100a will be substantially similar to the structures of the region 100c the stage of processing shown in FIG. 22A. In FIG. 22A, the N-type source/drain regions 140a have been formed at the region 100a (N-type source/drain regions 140c are also formed at the region 100c), substantially as described in relation to FIG. 10A.

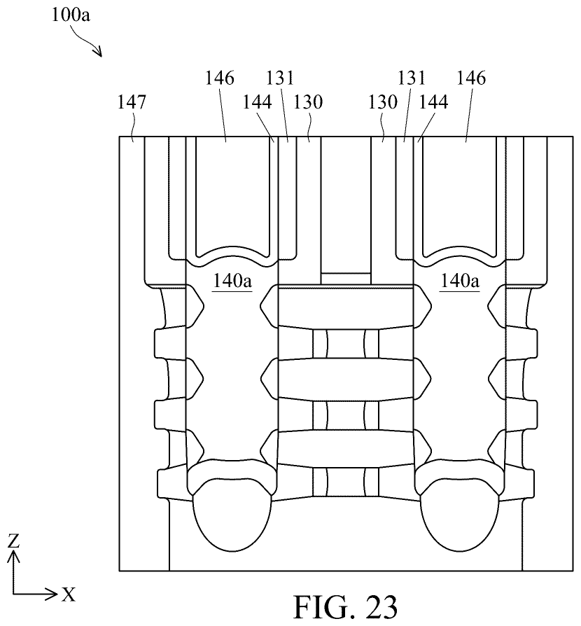

FIG. 23 illustrates the region 100a, in accordance with some embodiments. The CESL layer 144 and the interlevel dielectric layer 146 have been formed, substantially as described in relation to FIG. 11. These structures are also formed at the regions 100b-d.

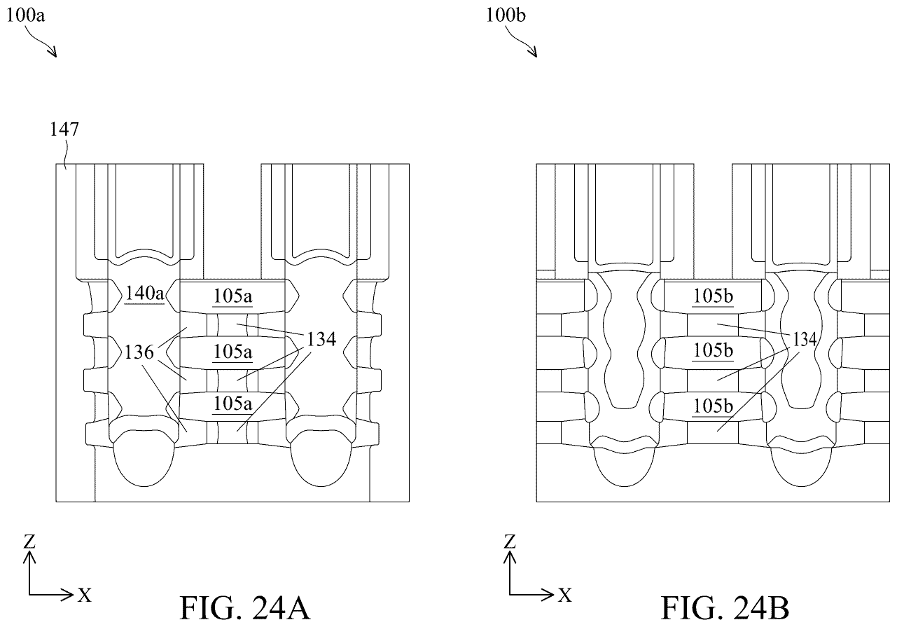

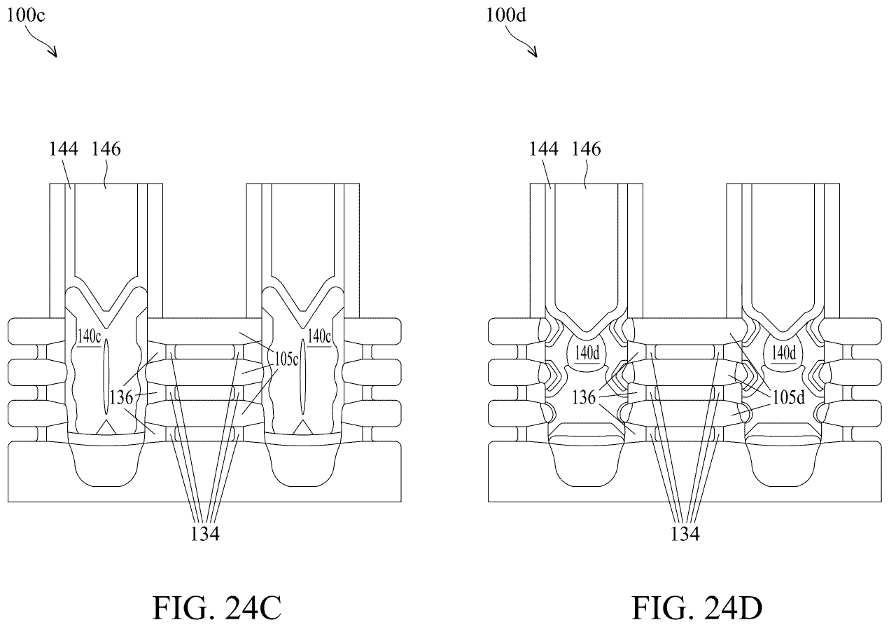

FIGS. 24A-D illustrate the regions 100a-d, in accordance with some embodiments. At the regions 100a-d, the sacrificial gate structure 118 has been removed substantially as described in relation to FIG. 12. At the regions 100a, 100c, and 100d, the sacrificial semiconductor nanostructures 107 have been removed substantially as described in relation to FIG. 12. At the region 100b, the large dielectric interposers 134 are present.

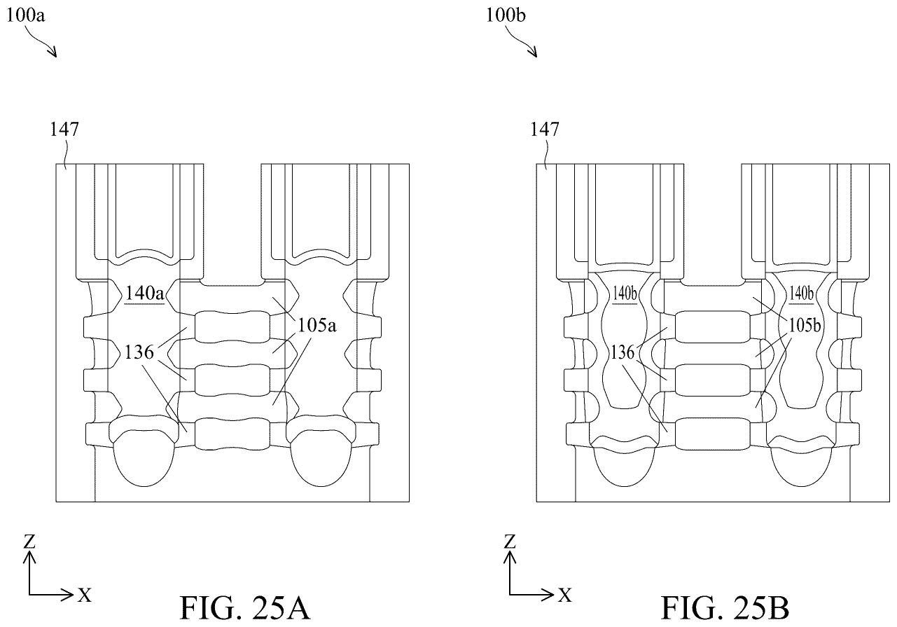

FIGS. 25A and 25B illustrate the regions 100a and 100b, in accordance with some embodiments. The processes described in relation to the regions 100a and 100b are also performed at the regions 100c and 100d. In FIGS. 25A and 25B, the dielectric interposers 134 have been removed, substantially as described in relation to FIG. 13.

The structure of the gate trench and channels 105 can be affected by etch selectivity between the material of the channels 105 the sacrificial semiconductor nanostructures one 07 and between the channels one 05 and the dielectric interposers. In an example in which the channels one 05 are silicon, the sacrificial semiconductor nanostructures one 07 are silicon germanium, and the dielectric interposers 134 are silicon oxide, removal of the silicon germanium also results in removing of a central portion of the silicon of the channels one 05. Removal of the silicon oxide does not result in significant etching of the channels one 05. The presence of the dielectric interposers 134 results in a smaller amount of etching of the channels one 05. The result is that there is a smaller difference in thickness between the center of the channels one 05 and the end portions of the channels one 05. In some embodiments, the difference in thickness is between 0 nm and 3 nm.

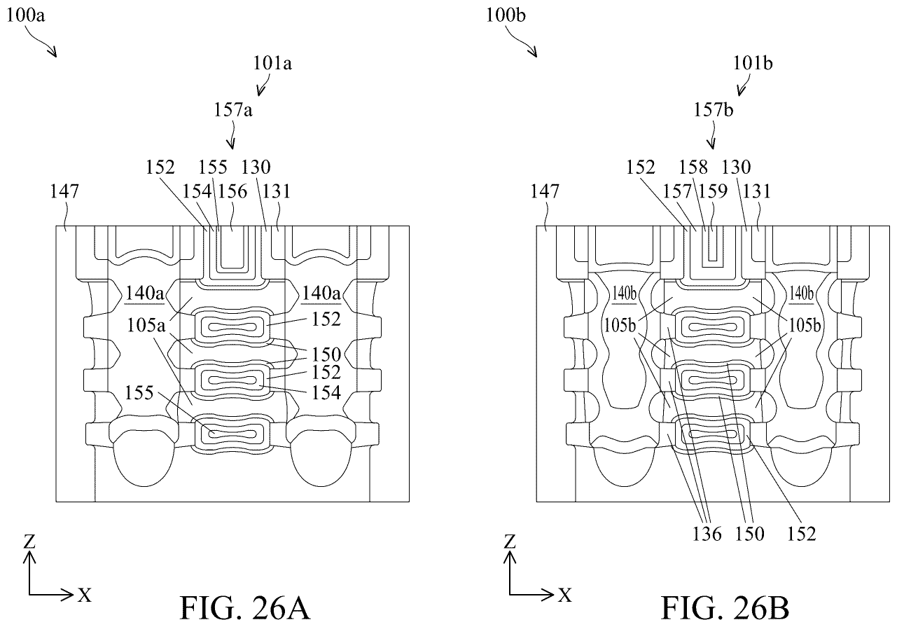

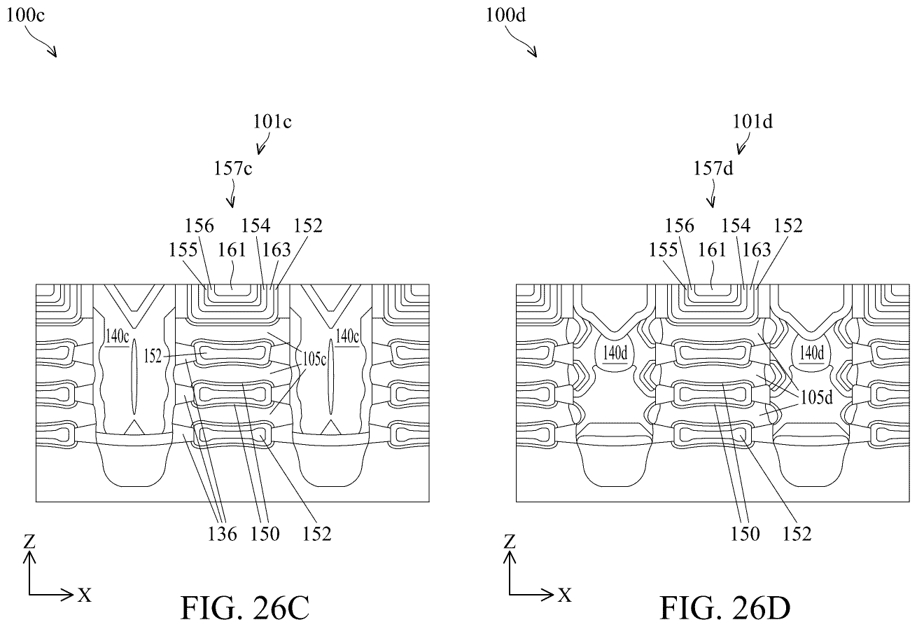

FIGS. 26A-D illustrate the regions 100a-d, in accordance with some embodiments. At the regions 100a-d, the interfacial gate dielectric layer 150 and the high K gate dielectric layer have been formed substantially as described in relation to FIGS. 14A-D. The gate electrodes 157a-d have also been formed, substantially as described in relation to FIGS. 14A-14D. At the stage of processing shown in FIGS. 26A-26D, formation of the transistors 101a-d is substantially complete. In particular, a short channel N-type transistor 101a, a short channel P-type transistor 101b, a long channel N-type transistor 101c, and a long channel N-type transistor 101d have been formed.

In some embodiments, at the stage of processing shown in FIG. 17A-17D, the long channel P-type region 100d does not include the mask 166. Instead, the sacrificial semiconductor nanostructures 107d are entirely removed as described in relation to the short channel P-type region 100b. The large dielectric interposers 134 are also formed at the region 100, as shown for the region 100b in FIG. 19B. Processing continues for the region 100d as described for the region 100b. In this manner, the transistors of the long channel P-type region 100d receive the same benefits from utilization of a full dielectric interposers 134 as described in relation to the short channel P-type region 100b.

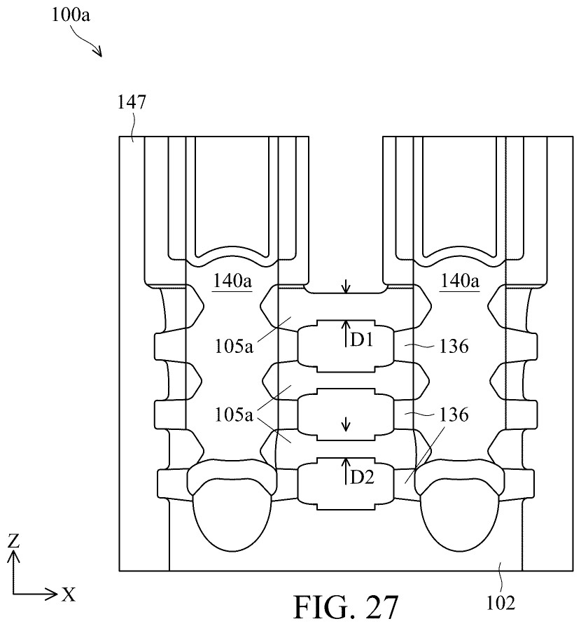

FIG. 27 illustrates the region 100a at the stage of processing shown in FIG. 13, in accordance with some embodiments. FIG. 27 illustrates a structural effect of removal of the sacrificial semiconductor nanostructures 107a and the dielectric interposers 134 at the region 100a. Due to the etch selectivity between the channels 105 and the sacrificial semiconductor nanostructures 107 the different than the etch selectivity between the channels 105 and the dielectric interposers 134, there is a difference in thickness between the highest channel 105 and the lowest channel 105. When the sacrificial semiconductor nanostructures 107a are removed, there are some removal of the material of the channels 105. When the dielectric interposer 134 is removed, a lesser amount of the channels 105 is also removed. The lowest channels are more effective than the highest channels, resulting in a thickness dimension D1 of a top channel and a smaller thickness dimension D2 of the lowest channel. In some embodiments, D1 is between 3 nm and 30 nm. In some embodiments, D2 is between 20 nm and 100 nm. In some embodiments, the difference between D1 and D2 can be between 0 nm and 3 nm.

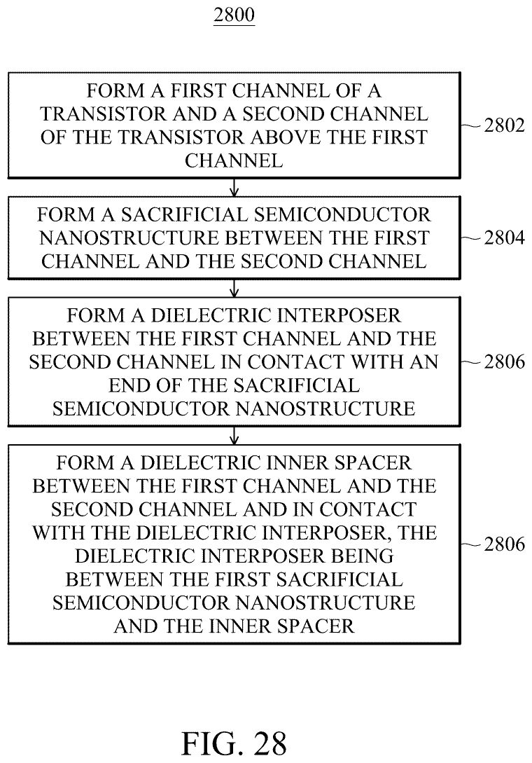

FIG. 28 is a flow diagram of a method 2800 for forming an integrated circuit, in accordance with some embodiments. The method 2800 can utilize the structures, processes, and systems described in relation to FIGS. 1-27. At 2802, the method 2800 includes forming a first channel of a transistor and a second channel of the transistor above the first channel. One example of first and second channels are two of the channels 105a of FIG. 10A. At 2804, the method 2800 includes forming a sacrificial semiconductor nanostructure between the first channel and the second channel. One example of the sacrificial semiconductor nanostructure is the sacrificial semiconductor nanostructure 107a of FIG. 10A. At 2806, the method 2800 includes forming a dielectric interposer between the first channel and the second channel in contact with an end of the sacrificial semiconductor nanostructure. One example of a dielectric interposer is the dielectric interposer 134 of FIG. 10A. And 2808, the method 2800 includes forming a dielectric inner spacer between the first channel and the second channel and in contact with the dielectric interposer, the dielectric interposer being between the first sacrificial semiconductor nanostructure and the inner spacer. The dielectric inner spacer is the inner spacer 136 of FIG. 10A.

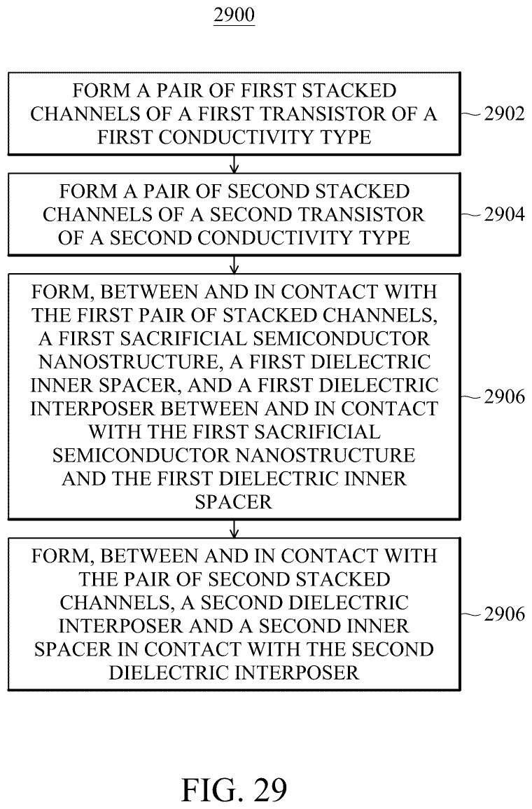

FIG. 29 is a flow diagram of a method 2900 for forming an integrated circuit, in accordance with some embodiments. The method 2900 can utilize the structures, processes, and systems described in relation to FIGS. 1-27. At 2902, the method 2900 includes forming a pair of first stacked channels of a first transistor of a first conductivity type. One example of first stacked channels are the stacked channels 105a of FIG. 9. At 2904, the method 2900 includes forming a pair of second stacked channels of a second transistor of a second conductivity type. One example second stacked channels are the stacked channels 105b of FIG. 10B. At 2906, the method 2900 includes forming, between and in contact with the first pair of stacked channels, a first sacrificial semiconductor nanostructure, a first dielectric inner spacer, and a first dielectric interposer between and in contact with the first sacrificial semiconductor nanostructure and the first dielectric inner spacer. One example of a first sacrificial semiconductor nanostructure is the first sacrificial semiconductor nanostructure 107a of FIG. 10A. One example of a first inner spacer is the inner spacer 136 of FIG. 10A. One example of a first dielectric interposer is the dielectric interposer 134 of FIG. 10A. At 2908, the method 2900 includes forming, between and in contact with the pair of second stacked channels, a second dielectric interposer and a second inner spacer in contact with the second dielectric interposer. One example of a second dielectric interposer is the dielectric interposer 107b of FIG. 10B. One example of second inner spacers are the inner spacers 136 of FIG. 10B.

Embodiments of the disclosure provide an integrated circuit having gate all around transistors that receive the benefits of utilization of both sacrificial semiconductor nanostructures and dielectric interposers. At N-type transistors, sacrificial semiconductor nanostructure interposers are recessed and dielectric interposers are formed in the recesses. The dielectric interposers are then likewise recessed and inner spacers are then formed in the remaining recesses adjacent to the recessed dielectric interposers. The result is that N-type transistors do not suffer the drawbacks of full utilization of dielectric interposers and retain the beneficial strain from utilization of sacrificial semiconductor nanostructures as interposers. The P-type transistors either utilize the same recessed dielectric interposers or may utilize full dielectric interposers, thereby providing the P-type transistors with the beneficial strain of utilization of dielectric interposers. Furthermore, damage to interlevel dielectric layers and trench isolation regions by removal of full dielectric interposers is reduced. The result is transistors with higher performance and integrated circuits with less damage. Accordingly, wafer yields increase in addition to device performance.

In some embodiments, a method includes forming a first channel of a transistor and a second channel of the transistor above the first channel and forming a sacrificial semiconductor nanostructure between the first channel and the second channel. The method includes forming a dielectric interposer between the first channel and the second channel in contact with an end of the sacrificial semiconductor nanostructure and forming a dielectric inner spacer between the first channel and the second channel and in contact with the dielectric interposer. The dielectric interposer is between the first sacrificial semiconductor nanostructure and the inner spacer.

In some embodiments, a method includes forming a pair of first stacked channels of a first transistor of a first conductivity type and forming a pair of second stacked channels of a second transistor of a second conductivity type. The method includes forming, between and in contact with the first pair of stacked channels, a first sacrificial semiconductor nanostructure, a first dielectric inner spacer, and a first dielectric interposer between and in contact with the first sacrificial semiconductor nanostructure and the first dielectric inner spacer. The method includes forming, between and in contact with the pair of second stacked channels, a second dielectric interposer and a second inner spacer in contact with the second dielectric interposer.

In some embodiments, a device includes a first transistor. The first transistor of a first type includes a first channel and a second channel above the first channel. A vertical thickness of the first channel is less than a vertical thickness of the second channel. The first transistor includes a first gate metal wrapped around the first channel and the second channel, a first source/drain region in contact with the first channel and the second channel, and a first inner spacer in contact with the first source/drain region and between first source/drain region and the first gate metal.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a first channel of a transistor and a second channel of the transistor above the first channel;
forming a sacrificial semiconductor nanostructure between the first channel and the second channel;
forming a dielectric interposer between the first channel and the second channel in contact with an end of the sacrificial semiconductor nanostructure; and
forming a dielectric inner spacer between the first channel and the second channel and in contact with the dielectric interposer, the dielectric interposer being between the first sacrificial semiconductor nanostructure and the inner spacer.

2. The method of claim 1, comprising removing the sacrificial semiconductor nanostructure and forming a gate metal of the transistor in place of the sacrificial semiconductor nanostructure.

3. The method of claim 2, comprising removing the sacrificial semiconductor nanostructure and the dielectric interposer and forming the gate metal of the transistor in place of the sacrificial semiconductor nanostructure and the dielectric interposer.

4. The method of claim 3, comprising forming a source/drain region of the transistor in contact with the first channel and the second channel prior to removing the sacrificial semiconductor nanostructure and the dielectric interposer.

5. The method of claim 3, wherein the dielectric interposer is selectively etchable with respect to the dielectric inner spacer.

6. The method of claim 1, wherein the second channel is vertically thicker than the first channel.

7. A method, comprising:
forming a pair of first stacked channels of a first transistor of a first conductivity type;
forming a pair of second stacked channels of a second transistor of a second conductivity type;
forming, between and in contact with the first pair of stacked channels, a first sacrificial semiconductor nanostructure, a first dielectric inner spacer, and a first dielectric interposer between the first sacrificial semiconductor nanostructure and the first dielectric inner spacer; and
forming, between and in contact with the pair of second stacked channels, a second dielectric interposer and a second inner spacer in contact with the second dielectric interposer.

8. The method of claim 7, comprising forming a second sacrificial semiconductor nanostructure between the second pair of stacked channels and in contact with the second dielectric inner spacer.

9. The method of claim 8, comprising:
removing the first sacrificial semiconductor nanostructure, the first dielectric interposer, the second sacrificial semiconductor nanostructure, and the second dielectric interposer;
forming a first gate metal in place of the first sacrificial semiconductor nanostructure and the first dielectric interposer; and
a second gate metal in place of the second sacrificial semiconductor nanostructure and the second dielectric interposer.

10. The method of claim of claim 7, comprising:
forming a second sacrificial semiconductor nanostructure between the pair of second channels;
forming a second dielectric interposer in place of the second sacrificial semiconductor nanostructure after entirely removing the second sacrificial semiconductor nanostructure; and
forming a pair of second inner spacers each between the pair of second channels and each in contact with the second dielectric interposer.

11. The method of claim 10, comprising:
removing the first sacrificial semiconductor nanostructure, the first dielectric interposer, and the second dielectric interposer;
forming a first gate metal in place of the first sacrificial semiconductor nanostructure and the first dielectric interposer; and
forming a second gate metal in place of the second dielectric interposer.

12. The method of claim 10, wherein forming the pair of first channels includes forming a first source/drain trench adjacent to the pair first channels in a first semiconductor fin, the method further comprising forming a mask in the first source/drain trench while removing the second sacrificial semiconductor nanostructure.

13 The method of claim 12, wherein the first conductivity type is N-type in the second conductivity type is P-type.

14. The method of claim 10, comprising:
forming a pair of third stacked channels of a third transistor of the second conductivity type; and
forming, between and in contact with the third pair of stacked channels, a third sacrificial semiconductor nanostructure, a third dielectric inner spacer, and a third dielectric interposer between and in contact with the third sacrificial semiconductor nanostructure and the third dielectric inner spacer.

15. The method of claim 7, wherein the first dielectric interposer is silicon oxide.

16. The method of claim 15, wherein forming the pair of third channels includes forming a source/drain trench adjacent to the pair of third channels in a semiconductor fin, the method further comprising forming a mask in the source/drain trench while removing the second sacrificial semiconductor nanostructure.

17. The method of claim 7, comprising:
forming a recess between the pair of first channels by recessing the first sacrificial semiconductor nanostructure;
forming the first dielectric interposer in the recess in contact with the first sacrificial semiconductor nanostructure;
reopening a portion of the recess by recessing the first dielectric interposer; and
forming the first inner spacer and the portion of the recess and in contact with the first dielectric interposer.

18. A device, comprising:
a first transistor of a first type including:
a first channel;
a second channel above the first channel, wherein a vertical thickness of the first channel is less than a vertical thickness of the second channel;
a first gate metal wrapped around the first channel and the second channel;
a first source/drain region in contact with the first channel and the second channel; and
a first inner spacer in contact with the first source/drain region and between first source/drain region and the first gate metal.

19. The device of claim 18, comprising:
a second transistor of a second type including:
a third channel;
a fourth channel above the third channel, wherein the vertical thickness of the third channel is less than a vertical thickness of the fourth channel;
a second gate metal wrapped around the third channel and the fourth channel;
a second source/drain region in contact with the third channel and the fourth channel; and
a second inner spacer in contact with the second source/drain region and between second source/drain region and the second gate metal.

20. The device of claim 18, wherein the first gate metal is formed in place of a sacrificial semiconductor nanostructure and the dielectric interposer.
